(19) United States
(12) Patent Application Publication
(10) Pub. No.: US 2026/0074826 A1
(43) Pub. Date: Mar. 12, 2026

(54) CYCLIC REDUNDANCY CHECK AND PARITY CHECK GENERATION FOR SYSTEMATIC POLAR CODING

(71) Applicant: QUALCOMM Incorporated, San Diego, CA (US)

(72) Inventors: Thomas Joseph RICHARDSON, South Orange, NJ (US); Wei YANG, San Diego, CA (US); Kirill IVANOV, La Jolla, CA (US); Gabi SARKIS, San Diego, CA (US); Jing JIANG, San Diego, CA (US)

(21) Appl. No.: 18/829,047

(22) Filed: Sep. 9, 2024

(51) Int. Cl. H04L 1/00

(52) U.S. Cl. CPC H04L 1/0057; H04L 1/0061

(57) ABSTRACT

Methods, systems, and devices for wireless communications are described. A wireless communication device may perform a systematic polar coding procedure including a first polar transform and a second polar transform such that a generated codeword includes information bits. For example, the wireless communication device may generate error check bits, such as cyclic redundancy check (CRC) or parity check (PC) bits, insert the error check bits prior to or after the first polar transform, and apply the first polar transform and the second polar transform to generate the codeword. In some examples, the wireless communication device may generate the error check bits such that the error check bits satisfy conditions associated with the systematic polar coding procedure. The wireless communication device may output the codeword based on the polar coding procedure, where the codeword includes the information bits.

### FIELD OF TECHNOLOGY

The following relates to wireless communications, including cyclic redundancy check (CRC) and parity check (PC) generation for systematic polar coding.

### BACKGROUND

Wireless communications systems are widely deployed to provide various types of communication content such as voice, video, packet data, messaging, broadcast, and so on. These systems may be capable of supporting communication with multiple users by sharing the available system resources (e.g., time, frequency, and power). Examples of such multiple-access systems include fourth generation (4G) systems such as Long Term Evolution (LTE) systems, LTE-Advanced (LTE-A) systems, or LTE-A Pro systems, and fifth generation (5G) systems which may be referred to as New Radio (NR) systems. These systems may employ technologies such as code division multiple access (CDMA), time division multiple access (TDMA), frequency division multiple access (FDMA), orthogonal FDMA (OFDMA), or discrete Fourier transform spread orthogonal frequency division multiplexing (DFT-S-OFDM). A wireless multiple-access communications system may include one or more base stations, each supporting wireless communication for communication devices, which may be known as user equipment (UE). Wireless communication devices may perform polar coding, such as non-systematic or systematic polar coding.

### SUMMARY

The systems, methods, and devices of this disclosure each have several innovative aspects, no single one of which is solely responsible for the desirable attributes disclosed herein.

A method for wireless communications by a wireless communication device is described. The method may include inserting one or more error check bits into a set of multiple information bits, where the one or more error check bits are inserted prior to a first polar transform of a systematic polar coding procedure on the set of multiple information bits, encoding the set of multiple information bits and the one or more error check bits to generate a codeword via the first polar transform and a second polar transform in accordance with the systematic polar coding procedure, where the codeword includes the set of multiple information bits and the one or more error check bits, and outputting the codeword based on the encoding.

A wireless communication device for wireless communications is described. The wireless communication device may include one or more memories storing processor executable code, and one or more processors coupled with the one or more memories. The one or more processors may individually or collectively be operable to execute the code to cause the wireless communication device to insert one or more error check bits into a set of multiple information bits, where the one or more error check bits are inserted prior to a first polar transform of a systematic polar coding procedure on the set of multiple information bits, encode the set of multiple information bits and the one or more error check bits to generate a codeword via the first polar transform and a second polar transform in accordance with the systematic polar coding procedure, where the codeword includes the set of multiple information bits and the one or more error check bits, and output the codeword based on the encoding.

Another wireless communication device for wireless communications is described. The wireless communication device may include means for inserting one or more error check bits into a set of multiple information bits, where the one or more error check bits are inserted prior to a first polar transform of a systematic polar coding procedure on the set of multiple information bits, means for encoding the set of multiple information bits and the one or more error check bits to generate a codeword via the first polar transform and a second polar transform in accordance with the systematic polar coding procedure, where the codeword includes the set of multiple information bits and the one or more error check bits, and means for outputting the codeword based on the encoding.

A non-transitory computer-readable medium storing code for wireless communications is described. The code may include instructions executable by one or more processors to insert one or more error check bits into a set of multiple information bits, where the one or more error check bits are inserted prior to a first polar transform of a systematic polar coding procedure on the set of multiple information bits, encode the set of multiple information bits and the one or more error check bits to generate a codeword via the first polar transform and a second polar transform in accordance with the systematic polar coding procedure, where the codeword includes the set of multiple information bits and the one or more error check bits, and output the codeword based on the encoding.

Some examples of the method, wireless communication devices, and non-transitory computer-readable medium described herein may further include operations, features, means, or instructions for identifying a first set of bit channels from a set of multiple bit channels based on a respective reliability level for each bit channel of the set of multiple bit channels, the first set of bit channels including one or more information bit channels, where a second set of bit channels of the set of multiple bit channels include one or more frozen bit channels and mapping the set of multiple information bits and the one or more error check bits to the first set of bit channels, where encoding the set of multiple information bits and the one or more error check bits may be based on the mapping.

In some examples of the method, wireless communication devices, and non-transitory computer-readable medium described herein, the one or more error check bits include one or more cyclic redundancy check (CRC) bits that may be based on the set of multiple information bits and the method, apparatuses, and non-transitory computer-readable medium may include further operations, features, means, or instructions for inserting one or more parity check (PC) bits after the first polar transform and prior to the second polar transform of the systematic polar coding procedure, where the one or more PC bits may be determined based on the set of multiple information bits and the one or more CRC bits.

In some examples of the method, wireless communication devices, and non-transitory computer-readable medium described herein, respective values of the one or more PC bits may be based on information bits of the set of multiple information bits at bit channels after the first polar transform having lower indices than an index of a respective PC bit of the one or more PC bits.

A method for wireless communications by a wireless communication device is described. The method may include encoding a set of multiple information bits and one or more error check bits via a first polar transform and a second polar transform of a systematic polar coding procedure to generate a codeword, where the encoding may include operations, features, means, or instructions for applying the first polar transform to the set of multiple information bits and inserting the one or more error check bits after the first polar transform and prior to the second polar transform and outputting the codeword based on the encoding via the first polar transform and the second polar transform, where the codeword includes the set of multiple information bits.

A wireless communication device for wireless communications is described. The wireless communication device may include one or more memories storing processor executable code, and one or more processors coupled with the one or more memories. The one or more processors may individually or collectively be operable to execute the code to cause the wireless communication device to encode a set of multiple information bits and one or more error check bits via a first polar transform and a second polar transform of a systematic polar coding procedure to generate a codeword, where, to the encode, the one or more processors are individually or collectively operable to execute the code to cause the wireless communication device to apply the first polar transform to the set of multiple information bits and insert the one or more error check bits after the first polar transform and prior to the second polar transform and output the codeword based on the encoding via the first polar transform and the second polar transform, where the codeword includes the set of multiple information bits.

Another wireless communication device for wireless communications is described. The wireless communication device may include means for encoding a set of multiple information bits and one or more error check bits via a first polar transform and a second polar transform of a systematic polar coding procedure to generate a codeword, where the means for the encoding include means for applying the first polar transform to the set of multiple information bits and means for inserting the one or more error check bits after the first polar transform and prior to the second polar transform and means for outputting the codeword based on the encoding via the first polar transform and the second polar transform, where the codeword includes the set of multiple information bits.

A non-transitory computer-readable medium storing code for wireless communications is described. The code may include instructions executable by one or more processors to encode a set of multiple information bits and one or more error check bits via a first polar transform and a second polar transform of a systematic polar coding procedure to generate a codeword, where the instructions to the encode are executable to apply the first polar transform to the set of multiple information bits and insert the one or more error check bits after the first polar transform and prior to the second polar transform and output the codeword based on the encoding via the first polar transform and the second polar transform, where the codeword includes the set of multiple information bits.

Some examples of the method, wireless communication devices, and non-transitory computer-readable medium described herein may further include operations, features, means, or instructions for identifying a first set of bit channels from a set of multiple bit channels based on a respective reliability level for each bit channel of the set of multiple bit channels, the first set of bit channels including one or more first bit channels including information bit channels, where a second set of bit channels of the set of multiple bit channels include frozen bit channels and mapping the set of multiple information bits to the first set of bit channels, where encoding the set of multiple information bits via the first polar transform may be based on the mapping.

Some examples of the method, wireless communication devices, and non-transitory computer-readable medium described herein may further include operations, features, means, or instructions for inserting one or more bits having bit values of zero into one or more second bit channels of the first set of bit channels prior to the first polar transform.

In some examples of the method, wireless communication devices, and non-transitory computer-readable medium described herein, inserting the one or more error check bits may include operations, features, means, or instructions for inserting the one or more error check bits into one or more second bit channels of the first set of bit channels.

Some examples of the method, wireless communication devices, and non-transitory computer-readable medium described herein may further include operations, features, means, or instructions for generating the one or more error check bits, where the one or more error check bits include one or more CRC bits, and where inserting the one or more CRC bits further includes and inserting the one or more CRC bits into the one or more second bit channels, where the one or more second bit channels precede the one or more first bit channels including the set of multiple information bits.

Some examples of the method, wireless communication devices, and non-transitory computer-readable medium described herein may further include operations, features, means, or instructions for identifying a polar reliability sequence that orders the respective reliability level for each bit channel of the set of multiple bit channels, where identifying the first set of bit channels may be based on identifying the polar reliability sequence.

In some examples of the method, wireless communication devices, and non-transitory computer-readable medium described herein, the codeword includes the set of multiple information bits based on the first set of bit channels and the one or more first bit channels satisfying a condition.

In some examples of the method, wireless communication devices, and non-transitory computer-readable medium described herein, for a first set including the first set of bit channels and for a second set including the second set of bit channels, the condition includes that one or more indices that may be larger than a respective element of a set of multiple elements of a set, based on a partial ordering, may be included in the set.

Some examples of the method, wireless communication devices, and non-transitory computer-readable medium described herein may further include operations, features, means, or instructions for determine the one or more error check bits in accordance with a CRC code associated with a CRC condition, where the one or more error check bits and the set of multiple information bits satisfy the CRC condition, and where inserting the one or more error check bits may be based on determining the one or more error check bits.

Some examples of the method, wireless communication devices, and non-transitory computer-readable medium described herein may further include operations, features, means, or instructions for generating the one or more error check bits in accordance with a CRC condition, where inserting the one or more error check bits further includes and inserting the one or more error check bits into one or more second bit channels of a first set of bit channels, where the one or more error check bits may be inserted in an order of a first indexed bit channel to a last indexed bit channel of the one or more second bit channels.

Some examples of the method, wireless communication devices, and non-transitory computer-readable medium described herein may further include operations, features, means, or instructions for identifying a first set of bit channels from a set of multiple bit channels based on a respective reliability level for each bit channel of the set of multiple bit channels, the first set of bit channels including information bit channels, identifying a second set of bit channels from the set of multiple bit channels, the second set of bit channels including PC bit channels, identifying a third set of bit channels of the set of multiple bit channels, the third set of bit channels including frozen bit channels, and mapping the set of multiple information bits to the first set of bit channels, where encoding the set of multiple information bits via the first polar transform may be based on the mapping.

In some examples of the method, wireless communication devices, and non-transitory computer-readable medium described herein, inserting the one or more error check bits may include operations, features, means, or instructions for inserting the one or more error check bits into the second set of bit channels.

In some examples of the method, wireless communication devices, and non-transitory computer-readable medium described herein, respective values of one or more PC bits may be based on information bits of the set of multiple information bits at bit channels after the first polar transform with lower indices than an index of a respective PC bit of the one or more PC bits.

In some examples of the method, wireless communication devices, and non-transitory computer-readable medium described herein, the one or more error check bits include one or more CRC bits or one or more PC bits.

Some examples of the method, wireless communication devices, and non-transitory computer-readable medium described herein may further include operations, features, means, or instructions for inserting one or more CRC bits into the set of multiple information bits prior to the first polar transform, where the one or more CRC bits may be determined based on the set of multiple information bits and inserting the one or more error check bits after the first polar transform and prior to the second polar transform of the systematic polar coding procedure, where the one or more error check bits include one or more PC bits, and where the one or more PC bits may be determined based on the set of multiple information bits and the one or more error check bits.

In some examples of the method, wireless communication devices, and non-transitory computer-readable medium described herein, the one or more error check bits include one or more CRC bits and one or more PC bits and the method, apparatuses, and non-transitory computer-readable medium may include further operations, features, means, or instructions for inserting the one or more CRC bits after the first polar transform and prior to the second polar transform of the systematic polar coding procedure, where a first quantity of the one or more CRC bits satisfies a CRC condition and inserting the one or more PC bits after the first polar transform and prior to the second polar transform of the systematic polar coding procedure, where a second quantity of the one or more PC bits satisfies a PC relationship.

Details of one or more implementations of the subject matter described in this disclosure are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIGS. 1 and 2 show examples of wireless communications systems that support cyclic redundancy check (CRC) and parity check (PC) generation for systematic polar coding in accordance with one or more aspects of the present disclosure.

FIGS. 3 through 5 show examples of systematic polar coding procedures that support CRC and PC generation for systematic polar coding in accordance with one or more aspects of the present disclosure.

FIGS. 6 and 7 show examples of process flows that support CRC and PC generation for systematic polar coding in accordance with one or more aspects of the present disclosure.

FIGS. 8 and 9 show block diagrams of devices that support CRC and PC generation for systematic polar coding in accordance with one or more aspects of the present disclosure.

FIG. 10 shows a block diagram of a communications manager that supports CRC and PC generation for systematic polar coding in accordance with one or more aspects of the present disclosure.

FIG. 11 shows a diagram of a system including a device that supports CRC and PC generation for systematic polar coding in accordance with one or more aspects of the present disclosure.

FIGS. 12 through 15 show flowcharts illustrating methods that support CRC and PC generation for systematic polar coding in accordance with one or more aspects of the present disclosure.

### DETAILED DESCRIPTION

Polar codes may be used to reduce latency and power by providing efficient and relatively low-complexity decoding of wireless communications. Polar coding may involve assigning bits to different bit-channels and encoding the bits such that certain bit-channels (e.g., polar channels) are associated with an increased reliability, while other bit-channels are associated with a decreased reliability (such that respective bit channels are polarized). A device may sort the bit-channels by levels of reliability, such as by most reliable bit-channel to least reliable bit-channel. For example, bit channels may be associated with respective reliabilities, and a wireless communication device may assign known bits (e.g., frozen bits) to low-reliability bit channels and assign information bits to high-reliability bit channels. In such examples, bit channels associated with the relatively higher reliability may be associated with reduced noise compared to the relatively lower reliability bit channels.

Systematic polar coding may further improve on polar coding in various ways, where systematic polar codes may refer to polar codes in which information bits transparently appear as part of a generated codeword (whereas non-systematic polar codes may not have information bits transparently appearing as part of the codeword). Non-systematic polar codes may be modified into systematic polar codes, such as via repetition of a polar transform. In some examples (e.g., for binary uniform sources), systematic polar codes may provide the same performance as non-systematic polar codes (e.g., in terms of a block error rate (BLER)), while also providing some improved performance (e.g., an improved bit error rate (BER)). Additionally, systematic polar codes may support inclusion of additional information, such as information about a source of a transmission. In such cases, the inclusion of additional information may be used by a receiver for communication, decoding, or both, of subsequent messages from the source. In some cases, a wireless communication device may include one or more of a cyclic redundancy check (CRC) bits, parity check (PC) bits, or a combination thereof, in an encoded message to improve a performance of polar coding. However, some techniques may not support use of CRC, PC, or both for systematic polar coding. For example, some techniques may not support generation of a systematic codeword (e.g., appearance of information bits as part of the codeword) after CRC or PC insertion.

As described herein, a wireless communication device may support insertion of error check bits, such as CRC or PC bits, in a systematic polar coding procedure. Systematic polar coding procedures described herein may involve a first polar coding transform and a second polar coding transform. In a first example, a wireless communication device may insert the error check bits (e.g., CRC bits), with information bits, prior to the first polar coding transform of the systematic polar coding procedure. For example, the wireless communication device may insert the error check bits prior to a first polar coding transform in one or more locations associated with a relatively high reliability level (e.g., locations assigned to information bits, rather than frozen bits). In some examples, locations of the CRC bits and the information bits may satisfy a condition, such as a condition associated with generating a systematic codeword. In the first example, because the error check bits are inserted prior to the first polar coding transform, the codeword (e.g., after performing the first polar transform and a second polar transform) may include (e.g., transparently) both the error check bits and the information bits.

In a second example, a wireless communication device may insert the error check bits after a first polar coding transform but before a second polar coding transform of the systematic polar coding operation. For example, the wireless communication device may select a first set of bit channels including one or more first bit channels associated with information bits and one or more second bit channels associated with error check bits. The wireless communication device may, after the first polar coding transform, insert the error check bits to the one or more second bit channels, leave the information bits in the one or more first bit channels unchanged, and set the remaining bit channels (e.g., for frozen bits) to zero. The information bits and the error check bits may (e.g., each) satisfy a condition such that a result of the second polar coding transform is a systematic codeword.

Aspects of the disclosure are initially described in the context of wireless communications systems. Aspects of the disclosure are also described in the context of exemplary systematic polar coding procedures and process flows. Aspects of the disclosure are further illustrated by and described with reference to apparatus diagrams, system diagrams, and flowcharts that relate to CRC and PC generation for systematic polar coding.

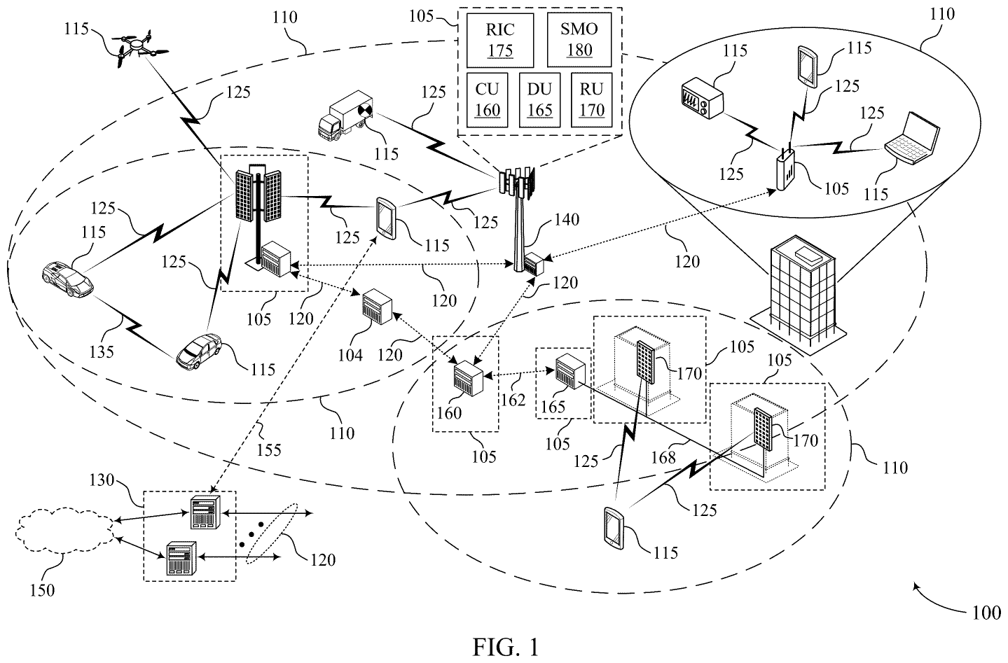

FIG. 1 shows an example of a wireless communications system 100 that supports CRC and PC generation for systematic polar coding in accordance with one or more aspects of the present disclosure. The wireless communications system 100 may include one or more devices, such as one or more network devices (e.g., network entities 105), one or more UEs 115, and a core network 130. In some examples, the wireless communications system 100 may be a Long Term Evolution (LTE) network, an LTE-Advanced (LTE-A) network, an LTE-A Pro network, a New Radio (NR) network, or a network operating in accordance with other systems and radio technologies, including future systems and radio technologies not explicitly mentioned herein.

The network entities 105 may be dispersed throughout a geographic area to form the wireless communications system 100 and may include devices in different forms or having different capabilities. In various examples, a network entity 105 may be referred to as a network element, a mobility element, a radio access network (RAN) node, or network equipment, among other nomenclature. In some examples, network entities 105 and UEs 115 may wirelessly communicate via communication link(s) 125 (e.g., a radio frequency (RF) access link). For example, a network entity 105 may support a coverage area 110 (e.g., a geographic coverage area) over which the UEs 115 and the network entity 105 may establish the communication link(s) 125. The coverage area 110 may be an example of a geographic area over which a network entity 105 and a UE 115 may support the communication of signals according to one or more radio access technologies (RATs).

The UEs 115 may be dispersed throughout a coverage area 110 of the wireless communications system 100, and each UE 115 may be stationary, or mobile, or both at different times. The UEs 115 may be devices in different forms or having different capabilities. Some example UEs 115 are illustrated in FIG. 1. The UEs 115 described herein may be capable of supporting communications with various types of devices in the wireless communications system 100 (e.g., other wireless communication devices, including UEs 115 or network entities 105), as shown in FIG. 1.

As described herein, a node of the wireless communications system 100, which may be referred to as a network node, or a wireless node, may be a network entity 105 (e.g., any network entity described herein), a UE 115 (e.g., any UE described herein), a network controller, an apparatus, a device, a computing system, one or more components, or another suitable processing entity configured to perform any of the techniques described herein. For example, a node may be a UE 115. As another example, a node may be a network entity 105. As another example, a first node may be configured to communicate with a second node or a third node. In one aspect of this example, the first node may be a UE 115, the second node may be a network entity 105, and the third node may be a UE 115. In another aspect of this example, the first node may be a UE 115, the second node may be a network entity 105, and the third node may be a network entity 105. In yet other aspects of this example, the first, second, and third nodes may be different relative to these examples. Similarly, reference to a UE 115, network entity 105, apparatus, device, computing system, or the like may include disclosure of the UE 115, network entity 105, apparatus, device, computing system, or the like being a node. For example, disclosure that a UE 115 is configured to receive information from a network entity 105 also discloses that a first node is configured to receive information from a second node.

In some examples, network entities 105 may communicate with a core network 130, or with one another, or both. For example, network entities 105 may communicate with the core network 130 via backhaul communication link(s) 120 (e.g., in accordance with an S1, N2, N3, or other interface protocol). In some examples, network entities 105 may communicate with one another via backhaul communication link(s) 120 (e.g., in accordance with an X2, Xn, or other interface protocol) either directly (e.g., directly between network entities 105) or indirectly (e.g., via the core network 130). In some examples, network entities 105 may communicate with one another via a midhaul communication link 162 (e.g., in accordance with a midhaul interface protocol) or a fronthaul communication link 168 (e.g., in accordance with a fronthaul interface protocol), or any combination thereof. The backhaul communication link(s) 120, midhaul communication links 162, or fronthaul communication links 168 may be or include one or more wired links (e.g., an electrical link, an optical fiber link) or one or more wireless links (e.g., a radio link, a wireless optical link), among other examples or various combinations thereof. A UE 115 may communicate with the core network 130 via a communication link 155.

One or more of the network entities 105 or network equipment described herein may include or may be referred to as a base station 140 (e.g., a base transceiver station, a radio base station, an NR base station, an access point, a radio transceiver, a NodeB, an eNodeB (eNB), a next-generation NodeB or giga-NodeB (either of which may be referred to as a gNB), a 5G NB, a next-generation eNB (ng-eNB), a Home NodeB, a Home eNodeB, or other suitable terminology). In some examples, a network entity 105 (e.g., a base station 140) may be implemented in an aggregated (e.g., monolithic, standalone) base station architecture, which may be configured to utilize a protocol stack that is physically or logically integrated within one network entity (e.g., a network entity 105 or a single RAN node, such as a base station 140).

In some examples, a network entity 105 may be implemented in a disaggregated architecture (e.g., a disaggregated base station architecture, a disaggregated RAN architecture), which may be configured to utilize a protocol stack that is physically or logically distributed among multiple network entities (e.g., network entities 105), such as an integrated access and backhaul (IAB) network, an open RAN (O-RAN) (e.g., a network configuration sponsored by the O-RAN Alliance), or a virtualized RAN (vRAN) (e.g., a cloud RAN (C-RAN)). For example, a network entity 105 may include one or more of a central unit (CU), such as a CU 160, a distributed unit (DU), such as a DU 165, a radio unit (RU), such as an RU 170, a RAN Intelligent Controller (RIC), such as an RIC 175 (e.g., a Near-Real Time RIC (Near-RT RIC), a Non-Real Time RIC (Non-RT RIC)), a Service Management and Orchestration (SMO) system, such as an SMO system 180, or any combination thereof. An RU 170 may also be referred to as a radio head, a smart radio head, a remote radio head (RRH), a remote radio unit (RRU), or a transmission reception point (TRP). One or more components of the network entities 105 in a disaggregated RAN architecture may be co-located, or one or more components of the network entities 105 may be located in distributed locations (e.g., separate physical locations). In some examples, one or more of the network entities 105 of a disaggregated RAN architecture may be implemented as virtual units (e.g., a virtual CU (VCU), a virtual DU (VDU), a virtual RU (VRU)).

The split of functionality between a CU 160, a DU 165, and an RU 170 is flexible and may support different functionalities depending on which functions (e.g., network layer functions, protocol layer functions, baseband functions, RF functions, or any combinations thereof) are performed at a CU 160, a DU 165, or an RU 170. For example, a functional split of a protocol stack may be employed between a CU 160 and a DU 165 such that the CU 160 may support one or more layers of the protocol stack and the DU 165 may support one or more different layers of the protocol stack. In some examples, the CU 160 may host upper protocol layer (e.g., layer 3 (L3), layer 2 (L2)) functionality and signaling (e.g., Radio Resource Control (RRC), service data adaptation protocol (SDAP), Packet Data Convergence Protocol (PDCP)). The CU 160 (e.g., one or more CUs) may be connected to a DU 165 (e.g., one or more DUs) or an RU 170 (e.g., one or more RUs), or some combination thereof, and the DUs 165, RUs 170, or both may host lower protocol layers, such as layer 1 (L1) (e.g., physical (PHY) layer) or L2 (e.g., radio link control (RLC) layer, medium access control (MAC) layer) functionality and signaling, and may each be at least partially controlled by the CU 160. Additionally, or alternatively, a functional split of the protocol stack may be employed between a DU 165 and an RU 170 such that the DU 165 may support one or more layers of the protocol stack and the RU 170 may support one or more different layers of the protocol stack. The DU 165 may support one or multiple different cells (e.g., via one or multiple different RUs, such as an RU 170). In some cases, a functional split between a CU 160 and a DU 165 or between a DU 165 and an RU 170 may be within a protocol layer (e.g., some functions for a protocol layer may be performed by one of a CU 160, a DU 165, or an RU 170, while other functions of the protocol layer are performed by a different one of the CU 160, the DU 165, or the RU 170). A CU 160 may be functionally split further into CU control plane (CU-CP) and CU user plane (CU-UP) functions. A CU 160 may be connected to a DU 165 via a midhaul communication link 162 (e.g., F1, F1-c, F1-u), and a DU 165 may be connected to an RU 170 via a fronthaul communication link 168 (e.g., open fronthaul (FH) interface). In some examples, a midhaul communication link 162 or a fronthaul communication link 168 may be implemented in accordance with an interface (e.g., a channel) between layers of a protocol stack supported by respective network entities (e.g., one or more of the network entities 105) that are in communication via such communication links.

In some wireless communications systems (e.g., the wireless communications system 100), infrastructure and spectral resources for radio access may support wireless backhaul link capabilities to supplement wired backhaul connections, providing an IAB network architecture (e.g., to a core network 130). In some cases, in an IAB network, one or more of the network entities 105 (e.g., network entities 105 or IAB node(s) 104) may be partially controlled by each other. The IAB node(s) 104 may be referred to as a donor entity or an IAB donor. A DU 165 or an RU 170 may be partially controlled by a CU 160 associated with a network entity 105 or base station 140 (such as a donor network entity or a donor base station). The one or more donor entities (e.g., IAB donors) may be in communication with one or more additional devices (e.g., IAB node(s) 104) via supported access and backhaul links (e.g., backhaul communication link(s) 120). IAB node(s) 104 may include an IAB mobile termination (IAB-MT) controlled (e.g., scheduled) by one or more DUs (e.g., DUs 165) of a coupled IAB donor. An IAB-MT may be equipped with an independent set of antennas for relay of communications with UEs 115 or may share the same antennas (e.g., of an RU 170) of IAB node(s) 104 used for access via the DU 165 of the IAB node(s) 104 (e.g., referred to as virtual IAB-MT (vIAB-MT)). In some examples, the IAB node(s) 104 may include one or more DUs (e.g., DUs 165) that support communication links with additional entities (e.g., IAB node(s) 104, UEs 115) within the relay chain or configuration of the access network (e.g., downstream). In such cases, one or more components of the disaggregated RAN architecture (e.g., the IAB node(s) 104 or components of the IAB node(s) 104) may be configured to operate according to the techniques described herein.

In the case of the techniques described herein applied in the context of a disaggregated RAN architecture, one or more components of the disaggregated RAN architecture may be configured to support test as described herein. For example, some operations described as being performed by a UE 115 or a network entity 105 (e.g., a base station 140) may additionally, or alternatively, be performed by one or more components of the disaggregated RAN architecture (e.g., components such as an IAB node, a DU 165, a CU 160, an RU 170, an RIC 175, an SMO system 180).

A UE 115 may include or may be referred to as a mobile device, a wireless device, a remote device, a handheld device, or a subscriber device, or some other suitable terminology, where the “device” may also be referred to as a unit, a station, a terminal, or a client, among other examples. A UE 115 may also include or may be referred to as a personal electronic device such as a cellular phone, a personal digital assistant (PDA), a tablet computer, a laptop computer, or a personal computer. In some examples, a UE 115 may include or be referred to as a wireless local loop (WLL) station, an Internet of Things (IoT) device, an Internet of Everything (IoE) device, or a machine type communications (MTC) device, among other examples, which may be implemented in various objects such as appliances, vehicles, or meters, among other examples.

The UEs 115 described herein may be able to communicate with various types of devices, such as UEs 115 that may sometimes operate as relays, as well as the network entities 105 and the network equipment including macro eNBs or gNBs, small cell eNBs or gNBs, or relay base stations, among other examples, as shown in FIG. 1.

The UEs 115 and the network entities 105 may wirelessly communicate with one another via the communication link(s) 125 (e.g., one or more access links) using resources associated with one or more carriers. The term “carrier” may refer to a set of RF spectrum resources having a defined PHY layer structure for supporting the communication link(s) 125. For example, a carrier used for the communication link(s) 125 may include a portion of an RF spectrum band (e.g., a bandwidth part (BWP)) that is operated according to one or more PHY layer channels for a given RAT (e.g., LTE, LTE-A, LTE-A Pro, NR). Each PHY layer channel may carry acquisition signaling (e.g., synchronization signals, system information), control signaling that coordinates operation for the carrier, user data, or other signaling. The wireless communications system 100 may support communication with a UE 115 using carrier aggregation or multi-carrier operation. A UE 115 may be configured with multiple downlink component carriers and one or more uplink component carriers according to a carrier aggregation configuration. Carrier aggregation may be used with both frequency division duplexing (FDD) and time division duplexing (TDD) component carriers. Communication between a network entity 105 and other devices may refer to communication between the devices and any portion (e.g., entity, sub-entity) of a network entity 105. For example, the terms “transmitting,” “receiving,” or “communicating,” when referring to a network entity 105, may refer to any portion of a network entity 105 (e.g., a base station 140, a CU 160, a DU 165, a RU 170) of a RAN communicating with another device (e.g., directly or via one or more other network entities, such as one or more of the network entities 105).

Signal waveforms transmitted via a carrier may be made up of multiple subcarriers (e.g., using multi-carrier modulation (MCM) techniques such as orthogonal frequency division multiplexing (OFDM) or discrete Fourier transform spread OFDM (DFT-S-OFDM)). In a system employing MCM techniques, a resource element may refer to resources of one symbol period (e.g., a duration of one modulation symbol) and one subcarrier, in which case the symbol period and subcarrier spacing may be inversely related. The quantity of bits carried by each resource element may depend on the modulation scheme (e.g., the order of the modulation scheme, the coding rate of the modulation scheme, or both), such that a relatively higher quantity of resource elements (e.g., in a transmission duration) and a relatively higher order of a modulation scheme may correspond to a relatively higher rate of communication. A wireless communications resource may refer to a combination of an RF spectrum resource, a time resource, and a spatial resource (e.g., a spatial layer, a beam), and the use of multiple spatial resources may increase the data rate or data integrity for communications with a UE 115.

The time intervals for the network entities 105 or the UEs 115 may be expressed in multiples of a basic time unit which may, for example, refer to a sampling period of Tₛ=1/(Δfₘₐₓ·N_{f}) seconds, for which Δfₘₐₓ may represent a supported subcarrier spacing, and N_{f} may represent a supported discrete Fourier transform (DFT) size. Time intervals of a communications resource may be organized according to radio frames each having a specified duration (e.g., 10 milliseconds (ms)). Each radio frame may be identified by a system frame number (SFN) (e.g., ranging from 0 to 1023).

Each frame may include multiple consecutively-numbered subframes or slots, and each subframe or slot may have the same duration. In some examples, a frame may be divided (e.g., in the time domain) into subframes, and each subframe may be further divided into a quantity of slots. Alternatively, each frame may include a variable quantity of slots, and the quantity of slots may depend on subcarrier spacing. Each slot may include a quantity of symbol periods (e.g., depending on the length of the cyclic prefix prepended to each symbol period). In some wireless communications systems, such as the wireless communications system 100, a slot may further be divided into multiple mini-slots associated with one or more symbols. Excluding the cyclic prefix, each symbol period may be associated with one or more (e.g., N_{f}) sampling periods. The duration of a symbol period may depend on the subcarrier spacing or frequency band of operation.

A subframe, a slot, a mini-slot, or a symbol may be the smallest scheduling unit (e.g., in the time domain) of the wireless communications system 100 and may be referred to as a transmission time interval (TTI). In some examples, the TTI duration (e.g., a quantity of symbol periods in a TTI) may be variable. Additionally, or alternatively, the smallest scheduling unit of the wireless communications system 100 may be dynamically selected (e.g., in bursts of shortened TTIs (sTTIs)).

Physical channels may be multiplexed for communication using a carrier according to various techniques. A physical control channel and a physical data channel may be multiplexed for signaling via a downlink carrier, for example, using one or more of time division multiplexing (TDM) techniques, frequency division multiplexing (FDM) techniques, or hybrid TDM-FDM techniques. A control region (e.g., a control resource set (CORESET)) for a physical control channel may be defined by a set of symbol periods and may extend across the system bandwidth or a subset of the system bandwidth of the carrier. One or more control regions (e.g., CORESETs) may be configured for a set of the UEs 115. For example, one or more of the UEs 115 may monitor or search control regions for control information according to one or more search space sets, and each search space set may include one or multiple control channel candidates in one or more aggregation levels arranged in a cascaded manner. An aggregation level for a control channel candidate may refer to an amount of control channel resources (e.g., control channel elements (CCEs)) associated with encoded information for a control information format having a given payload size. Search space sets may include common search space sets configured for sending control information to UEs 115 (e.g., one or more UEs) or may include UE-specific search space sets for sending control information to a UE 115 (e.g., a specific UE).

In some examples, a network entity 105 (e.g., a base station 140, an RU 170) may be movable and therefore provide communication coverage for a moving coverage area, such as the coverage area 110. In some examples, coverage areas 110 (e.g., different coverage areas) associated with different technologies may overlap, but the coverage areas 110 (e.g., different coverage areas) may be supported by the same network entity (e.g., a network entity 105). In some other examples, overlapping coverage areas, such as a coverage area 110, associated with different technologies may be supported by different network entities (e.g., the network entities 105). The wireless communications system 100 may include, for example, a heterogeneous network in which different types of the network entities 105 support communications for coverage areas 110 (e.g., different coverage areas) using the same or different RATs.

The wireless communications system 100 may be configured to support ultra-reliable communications or low-latency communications, or various combinations thereof. For example, the wireless communications system 100 may be configured to support ultra-reliable low-latency communications (URLLC). The UEs 115 may be designed to support ultra-reliable, low-latency, or critical functions. Ultra-reliable communications may include private communication or group communication and may be supported by one or more services such as push-to-talk, video, or data. Support for ultra-reliable, low-latency functions may include prioritization of services, and such services may be used for public safety or general commercial applications. The terms ultra-reliable, low-latency, and ultra-reliable low-latency may be used interchangeably herein.

In some examples, a UE 115 may be configured to support communicating directly with other UEs (e.g., one or more of the UEs 115) via a device-to-device (D2D) communication link, such as a D2D communication link 135 (e.g., in accordance with a peer-to-peer (P2P), D2D, or sidelink protocol). In some examples, one or more UEs 115 of a group that are performing D2D communications may be within the coverage area 110 of a network entity 105 (e.g., a base station 140, an RU 170), which may support aspects of such D2D communications being configured by (e.g., scheduled by) the network entity 105. In some examples, one or more UEs 115 of such a group may be outside the coverage area 110 of a network entity 105 or may be otherwise unable to or not configured to receive transmissions from a network entity 105. In some examples, groups of the UEs 115 communicating via D2D communications may support a one-to-many (1:M) system in which each UE 115 transmits to one or more of the UEs 115 in the group. In some examples, a network entity 105 may facilitate the scheduling of resources for D2D communications. In some other examples, D2D communications may be carried out between the UEs 115 without an involvement of a network entity 105.

The core network 130 may provide user authentication, access authorization, tracking, Internet Protocol (IP) connectivity, and other access, routing, or mobility functions. The core network 130 may be an evolved packet core (EPC) or 5G core (5GC), which may include at least one control plane entity that manages access and mobility (e.g., a mobility management entity (MME), an access and mobility management function (AMF)) and at least one user plane entity that routes packets or interconnects to external networks (e.g., a serving gateway (S-GW), a Packet Data Network (PDN) gateway (P-GW), or a user plane function (UPF)). The control plane entity may manage non-access stratum (NAS) functions such as mobility, authentication, and bearer management for the UEs 115 served by the network entities 105 (e.g., base stations 140) associated with the core network 130. User IP packets may be transferred through the user plane entity, which may provide IP address allocation as well as other functions. The user plane entity may be connected to IP services 150 for one or more network operators. The IP services 150 may include access to the Internet, Intranet(s), an IP Multimedia Subsystem (IMS), or a Packet-Switched Streaming Service.

The wireless communications system 100 may operate using one or more frequency bands, which may be in the range of 300 megahertz (MHz) to 300 gigahertz (GHz). Generally, the region from 300 MHz to 3 GHz is known as the ultra-high frequency (UHF) region or decimeter band because the wavelengths range from approximately one decimeter to one meter in length. UHF waves may be blocked or redirected by buildings and environmental features, which may be referred to as clusters, but the waves may penetrate structures sufficiently for a macro cell to provide service to the UEs 115 located indoors. Communications using UHF waves may be associated with smaller antennas and shorter ranges (e.g., less than one hundred kilometers) compared to communications using the smaller frequencies and longer waves of the high frequency (HF) or very high frequency (VHF) portion of the spectrum below 300 MHz.

The wireless communications system 100 may utilize both licensed and unlicensed RF spectrum bands. For example, the wireless communications system 100 may employ License Assisted Access (LAA), LTE-Unlicensed (LTE-U) RAT, or NR technology using an unlicensed band such as the 5 GHz industrial, scientific, and medical (ISM) band. While operating using unlicensed RF spectrum bands, devices such as the network entities 105 and the UEs 115 may employ carrier sensing for collision detection and avoidance. In some examples, operations using unlicensed bands may be based on a carrier aggregation configuration in conjunction with component carriers operating using a licensed band (e.g., LAA). Operations using unlicensed spectrum may include downlink transmissions, uplink transmissions, P2P transmissions, or D2D transmissions, among other examples.

A network entity 105 (e.g., a base station 140, an RU 170) or a UE 115 may be equipped with multiple antennas, which may be used to employ techniques such as transmit diversity, receive diversity, multiple-input multiple-output (MIMO) communications, or beamforming. The antennas of a network entity 105 or a UE 115 may be located within one or more antenna arrays or antenna panels, which may support MIMO operations or transmit or receive beamforming. For example, one or more base station antennas or antenna arrays may be co-located at an antenna assembly, such as an antenna tower. In some examples, antennas or antenna arrays associated with a network entity 105 may be located at diverse geographic locations. A network entity 105 may include an antenna array with a set of rows and columns of antenna ports that the network entity 105 may use to support beamforming of communications with a UE 115. Likewise, a UE 115 may include one or more antenna arrays that may support various MIMO or beamforming operations. Additionally, or alternatively, an antenna panel may support RF beamforming for a signal transmitted via an antenna port.

Beamforming, which may also be referred to as spatial filtering, directional transmission, or directional reception, is a signal processing technique that may be used at a transmitting device or a receiving device (e.g., a network entity 105, a UE 115) to shape or steer an antenna beam (e.g., a transmit beam, a receive beam) along a spatial path between the transmitting device and the receiving device. Beamforming may be achieved by combining the signals communicated via antenna elements of an antenna array such that some signals propagating along particular orientations with respect to an antenna array experience constructive interference while others experience destructive interference. The adjustment of signals communicated via the antenna elements may include a transmitting device or a receiving device applying amplitude offsets, phase offsets, or both to signals carried via the antenna elements associated with the device. The adjustments associated with each of the antenna elements may be defined by a beamforming weight set associated with a particular orientation (e.g., with respect to the antenna array of the transmitting device or receiving device, or with respect to some other orientation).

The wireless communications system 100 may support the use of polar codes for wireless communications. Polar codes may be used to reduce latency and power. Polar coding may involve assigning bits to different bit-channels and encoding the bits such that certain bit-channels (e.g., polar channels) are polarized to an increase reliability, while other bit-channels are polarized to a decreased reliability. A device may sort the bit-channels by levels of reliability, such as by most reliable bit-channel to least reliable bit-channel. As an example, an encoder of a transmitting wireless communication device (e.g., a UE 115 or a network entity 105) may implement a polar code using a matrix that polarizes copies of a channel into subchannels (which may be referred to as bit channels) that are either relatively noisy (corresponding to decreased reliability) or relatively noiseless (corresponding to increased reliability). Information bits may be mapped to the relatively noiseless bit channels, and frozen bits (e.g., bits that may be known by both the transmitting wireless communication device and a receiving wireless communication device) may be mapped to the relatively noisy bit channels. The transmitting wireless communication device may transmit a codeword in accordance with the mapping to the respective bit channels. The sorted bit-channel order may depend on the capacity of the channel code. For a total of N bit-channels, to transmit using a rate R (e.g., encode the polar code with rate R), a transmitting device may transmit the information bits in K bit-channels, where K/N=R. In the other N−K bit-channels, the transmitting device may transmit frozen values known to both the receiver and transmitter. The value of R may depend on the channel capacity and the acceptable BER.

Polar codes may be linear codes that are non-systematic, and may be turned into a systematic code (e.g., polar codes may be encoded systematically). As such, a systematic polar code may refer to a polar code that includes information bits that transparently appear as part of the codeword. Systematic polar codes may have relatively improved BER performance and protection over regular (e.g., non-systematic) polar codes, while maintaining the same or similar BLER performance and relatively low-complexity properties associated with non-systematic polar codes.

Some systematic polar coding techniques may not support insertion of error check bits, such as CRC or PC bits, while using a relatively simple encoding scheme. For example, CRC or PC bits may not be inserted in linear codes converted from non-systematic to systematic by performing non-systematic encoding twice. However, techniques described herein support error check insertion for a systematic polar coding procedure involving application of two non-systematic linear codes (e.g., application of two polar coding transforms).

For example, systematic polar coding procedures described herein may involve a first polar coding transform and a second polar coding transform. A polar coding transform of a length N binary vector u may refer to a length N vector u*G. For example, G may be an N*N binary matrix obtained via a Kronecker product of a base 2×2 binary matrix [1,0; 1,1] with itself log₂ N times. In other words, G_{N}=(G₂)^{⊗n}, which may be an n^{th} Kronecker power of a matrix G₂, where

$${G}_{2} = [ \begin{matrix}1 & 0 \\ 1 & 1\end{matrix} ] ,$$

and where n=log₂ N. A wireless communication device, such as the UE 115 or the network entity 105, may insert error check bits (e.g., CRC bits), with information bits, prior to the first polar coding transform of the systematic polar coding procedure. That is, the wireless communication device may insert the error check bits prior to any polar coding transformation in one or more locations associated with a relatively high reliability level (e.g., locations assigned to information bits, rather than frozen bits). In some examples, locations of the CRC bits and the information bits may satisfy a condition, such as a condition associated with generating a systematic codeword. In such examples, because the error check bits are inserted prior to the first polar coding transform, the codeword may include (e.g., transparently) both the error check bits and the information bits. Alternatively, the wireless communication device may insert the error check bits after a first polar coding transform but before a second polar coding transform of the systematic polar coding operation. For example, the wireless communication device may select a first set of bit channels including one or more first bit channels associated with information bits and one or more second bit channels associated with error check bits. The wireless communication device may, after the first polar coding transform, insert the error check bits to the one or more second bit channels, leave the information bits in the one or more first bit channels unchanged, and set the remaining bit channels (e.g., for frozen bits) to zero. The information bits and the error check bits may (e.g., each) satisfy a condition such that a result of the second polar coding transform is systematic.

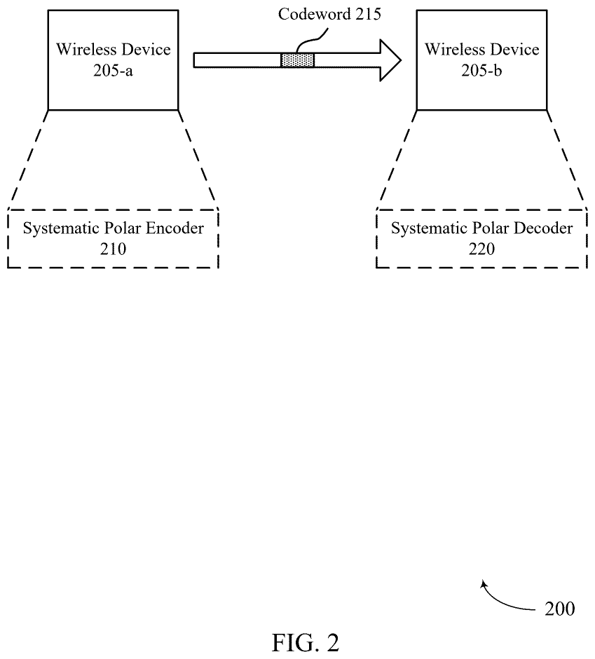

FIG. 2 shows an example of a wireless communications system 200 that supports CRC and PC generation for systematic polar coding in accordance with one or more aspects of the present disclosure. The wireless communications system 200 may implement or be implemented by aspects of the wireless communications system 100. For example, the wireless communications system 200 may illustrate and describe communications between a wireless device 205-a and a wireless device 205-b, which may be examples of network entities 105, UEs 115, or one or more other devices, as described with reference to FIG. 1.

In examples described herein, wireless devices may perform systematic polar coding according to a systematic polar coding procedure. The systematic polar coding procedure may involve converting a non-systematic linear code into a systematic linear code. For example, the wireless device 205-a may convert the non-systematic linear code into the systematic linear code by inverting at least a portion of a generator matrix. Additionally, or alternatively, the wireless device 205-a may convert the non-systematic linear code into the systematic linear code by performing non-systematic encoding twice. That is, the wireless device 205-a may implement systematic polar encoding by calling non-systematic encoding twice. As described herein, performing the non-systematic encoding twice may to implement the systematic polar encoding may refer to performance of a first polar coding transform and a second polar coding transform. For example, the wireless device 205-a may use a systematic polar encoder 210 to perform the systematic polar encoding procedure including the first polar coding transform and the second polar coding transform and generate a codeword 215.

By performing systematic polar coding, a location of information bits in the codeword 215 may be the same as a location of the information bits prior to the systematic polar coding procedure (e.g., prior to the first polar coding transform and the second polar coding transform). In some examples, for the location of the information bits to be the same before and after the systematic polar coding procedure, a sequence of the information bits may satisfy a condition (e.g., algebraic properties) associated with generating a systematic codeword (e.g., in which the information bits are transparent). To decode a codeword encoded in accordance with the systematic polar coding procedure, the wireless device 205-b may decode the polar code resulting from the second polar transform with a conventional decoder (e.g., successive cancellation list (SCL) decoder), decode the polar code resulting from the first polar transform, and convert (e.g., via the first polar transform) decoded bits of the polar code resulting from the first polar transform to obtain the information bits. Depending on context, information bits may refer to a data payload communicated between the wireless device 205-a and the wireless device 205-b (e.g., a transmitter and a receiver, respectively). In other cases, such as with the examples described herein with respect to the inclusion of CRC bits with information bits, the information bits may refer to bits (e.g., non-frozen bits) used by a polar encoder.

In some examples, the wireless device 205-a may include one or more error check bits in the codeword 215 such that the wireless device 205-b may determine an integrity of information in the codeword 215. For example, the wireless device 205-a may include one or more CRC bits, one or more PC bits, or both. The wireless device 205-b may verify an integrity of information included in the codeword 215 based on the included one or more CRC bits, the one or more PC bits, or both. For example, by including the one or more CRC bits, the one or more PC bits, or both, the wireless device 205-b may improve a performance level associated with polar coding. That is, to improve performance, polar codes may be concatenated with CRC bits, PC bits, or both.

In examples in which the wireless device 205-a includes the one or more PC bits, the wireless device 205-a may perform a PC polar coding procedure. One or more frozen bits, in the example of the PC polar coding procedure, may be functions of preceding information bits. For example, frozen bits, as used herein, may include static frozen bits (e.g., set to zero, fixed bits) and dynamic frozen bits (e.g., PC bits). Thus, static frozen bits, or frozen bits in some examples of CRC polar coding procedures and other polar coding procedures described herein, may refer to one or more bits set to zero. Further, dynamic frozen bits, or frozen bits in the example of the PC polar coding procedure, may refer to PC bits. As such, the frozen bits in a codeword including PC bits may be dynamic frozen bits, where each dynamic frozen bit is based on one or more preceding information bits (e.g., preceding according to a reliability index). Additionally, to preserve an SCL decoding order, values of PC bits may depend on the preceding information bits (e.g., according to a natural index). For example, a value of a PC bit on a channel i may be based on information bits in channels 0, . . . , i−1.

In examples in which the wireless device 205-a includes the one or more CRC bits, a bit sequence b₀, . . . , bₙ₋₁ may satisfy the CRC if Equation 1 below includes a CRC polynomial g(x) as a factor.

$${\sum }_{i = 0}^{n - 1} {b}_{i} {x}^{n - 1 - i} \qquad ( 1 )$$

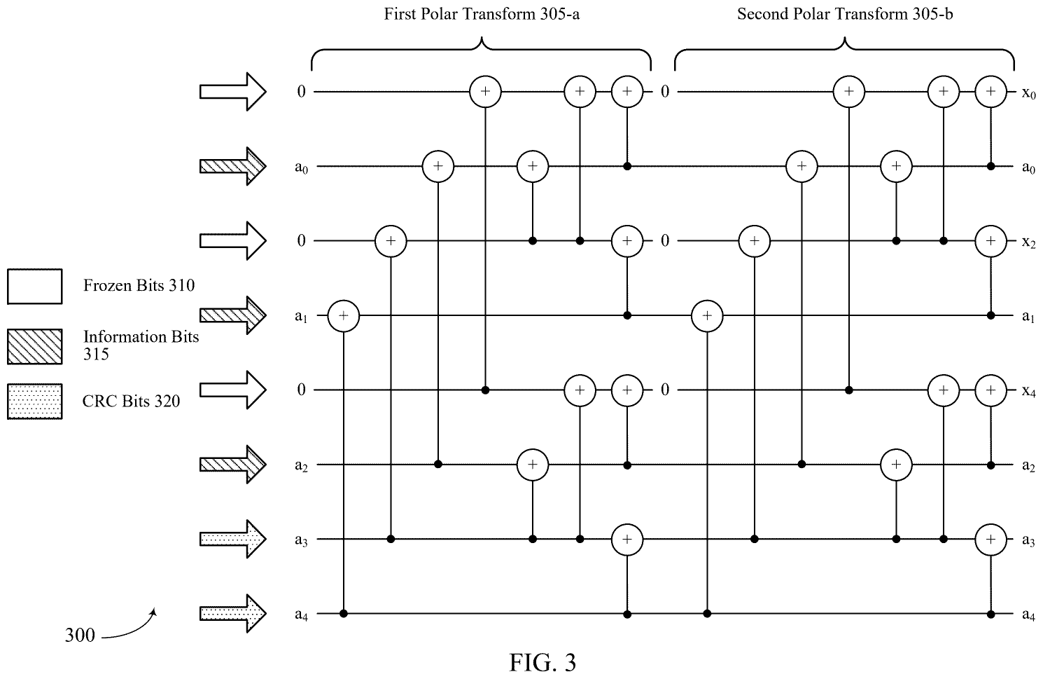

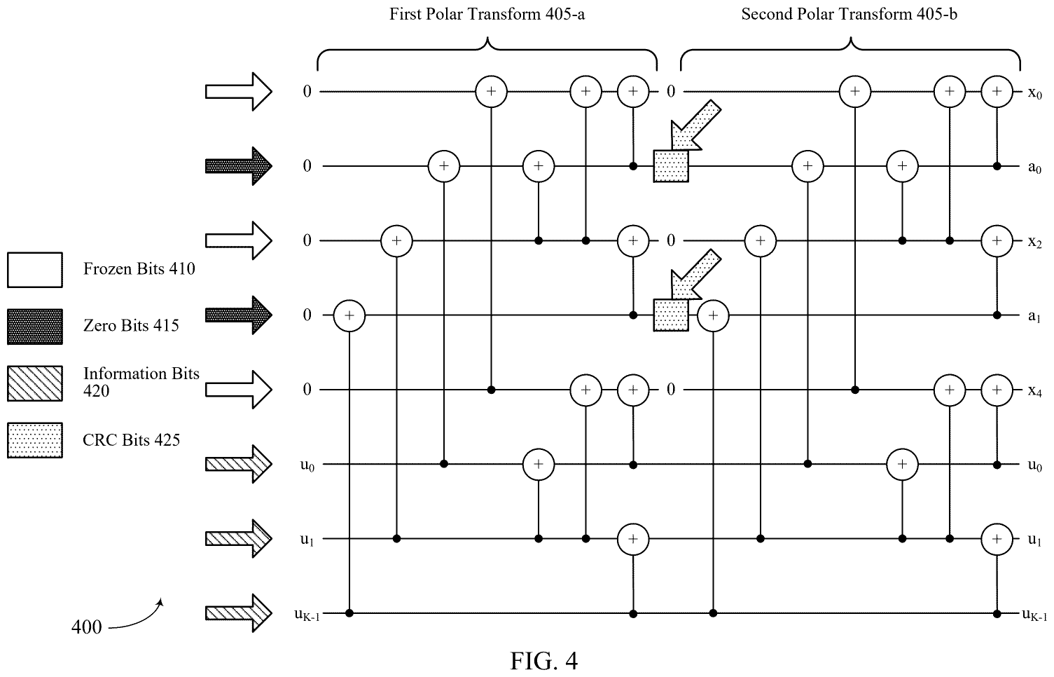

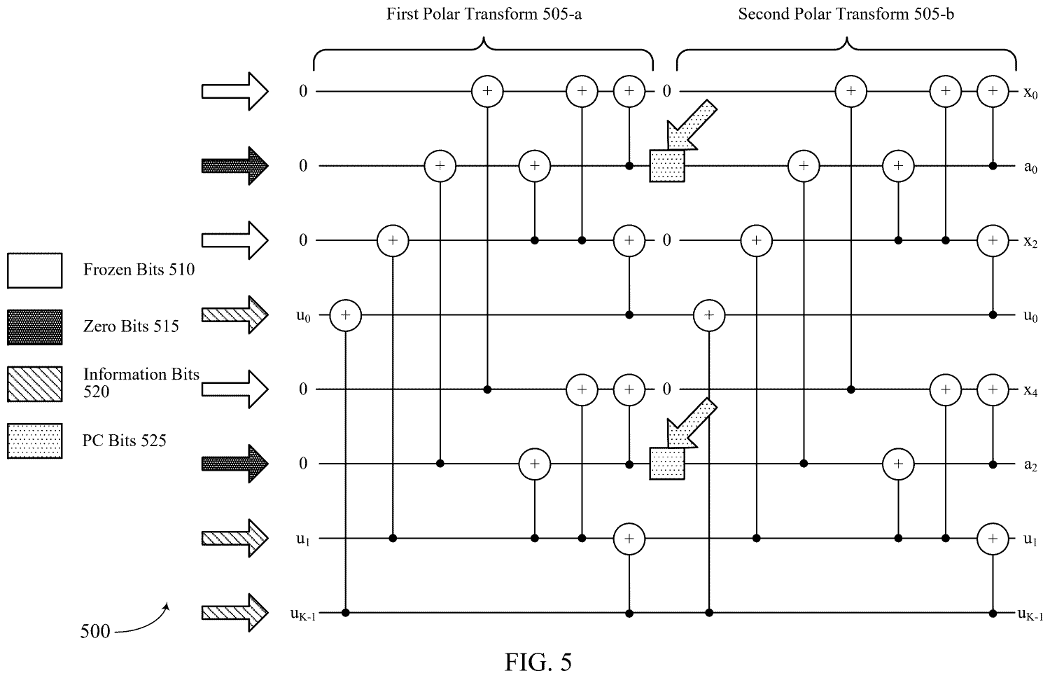

To support the inclusion of PC bits, CRC, bits, or both in a systematic codeword, the wireless device 205-a may perform systematic polar coding procedures described in further detail elsewhere herein, including with reference to FIGS. 3 through 5. The wireless device 205-a may perform a systematic polar coding procedure based on including a PC, a CRC, or both a PC and CRC in the codeword. In some cases, different systematic polar coding procedures described herein may correspond to different types or error checks. For example, the wireless device 205-a may use (e.g., apply, identify, select, or the like) the systematic polar coding procedures described with reference to FIGS. 3 and 4 for codewords that include a CRC (e.g., one or more CRC bits). The wireless device 205-a may use (e.g., apply, identify, select, or the like) the systematic polar coding procedure described with reference to FIG. 5 for codewords that include a PC (e.g., one or more PC bits). In some examples, the wireless device 205-a may use a combination of the systematic polar coding procedures described with reference to FIGS. 3 through 5 for codewords that include both CRC and PC bits. For example, the wireless device 205-a may use (e.g., apply, identify, select, or the like) a combination of the systematic polar coding procedures described with reference to FIGS. 3 and 5 or a combination of the systematic polar coding procedures described with reference to FIGS. 4 and 5 for codewords that include both CRC and PC bits.

The wireless device 205-b may receive the codeword 215 encoded via the systematic polar encoder 210. For example, the wireless device 205-b may decode the codeword 215 via (e.g., using, by applying, or the like) a systematic polar decoder 220. Decoding the codeword 215 via the systematic polar decoder 220 may involve a systematic polar decoding procedure in which the wireless device 205-b performs one or more polar transforms to decode the codeword 215. For example, the wireless device 205-b may perform the second polar coding transform on the bits of the codeword, and then perform the first polar coding transform to identify the bits inserted to one or more bit channels (e.g., originally). In other words, the systematic polar decoding procedure may correspond to a reverse order of one or more operations in the systematic polar encoding procedure.

FIG. 3 shows an example of a systematic polar coding procedure 300 that supports CRC and PC generation for systematic polar coding in accordance with one or more aspects of the present disclosure. The systematic polar coding procedure 300 may implement, or be implemented by, aspects of the wireless communications system 100, the wireless communications system 200, or both. For example, the systematic polar coding procedure 300 may be implemented by a wireless device, such as the wireless device 205-a as described with reference to FIG. 2.

In the example of FIG. 3, a wireless communication device may insert CRC bits 320 prior to a first polar transform 305-a. For example, the wireless communication device may insert the CRC bits 320 in a first domain (e.g., in a U domain). The wireless communication device may insert the CRC bits 320 as information bits 315. For example, for bit sequence of information bits a₀, a₁, a₂, a₃, a₄, the bits a₀, a₁, a₂ may correspond to information bits 315 and the bits a₃ and a₄ may correspond to CRC bits 320.

The wireless communication device may determine a reliability level associated with each bit channel of multiple bit channels. Based on the reliability levels, the wireless communication device may identify a first set of bit channels of the multiple bit channels, such as bit channels having highest reliability levels relative to other bit channels of the multiple bit channels. In the example of FIG. 3, the wireless communication device may identify K+L bit channels, where K may correspond to a quantity of information bits 315 and L may correspond to a quantity of CRC bits 320. In other words, the wireless communication device may identify a quantity of bit channels having highest reliability levels relative to the other bit channels, where the quantity corresponds to a sum of a quantity of the information bits 315 and a quantity of the CRC bits 320. The first set of bit channels may be information bit channels. A remaining set of bit channels, such as a second set of bit channels, may be frozen bit channels corresponding to frozen bits 310. For example, the second set of bit channels including the frozen bit channels may correspond to bit channels having lowest reliability levels relative to the other bit channels. The first set of bit channels and the second set of bit channels may be disjoint sets.

The wireless communication device may map the information bits 315 and the CRC bits 320 to the first set of bit channels based on identifying the first set of bit channels. For example, the wireless communication device may map the information bits 315 and the CRC bits 320 to the first set of bit channels identified as information bit channels. While the CRC bits 320 are illustrated in the example of FIG. 3 as being inserted to last channels of the first set of bit channels, it may be understood that the CRC bits 320 may be inserted in one or more other locations. In some examples, locations of the information bits 315 and the CRC bits 320 within the multiple bit channels (e.g., a sum of the locations of the information bits 315 and the CRC bits 320) may satisfy a condition. That is, locations of bit channels of the first set of bit channels may satisfy the condition. Locations of the information bits 315 and the CRC bits 320 within the first set of bit channels may not affect the condition being met. A codeword generated by the systematic polar coding procedure 300 may be systematic based on the locations of the information bits 315 and the CRC bits 320 satisfying the condition.

The wireless communication device may encode the information bits 315 and the CRC bits 320 via the first polar transform 305-a and the second polar transform 305-b. After the first polar transform 305-a, the wireless communication device may set bits (e.g., frozen bits 310) mapped to the frozen bit locations to zero while leaving the bits (e.g., information bits 315 and CRC bits 320) mapped to the first set of bit channels (e.g., information bit channels) unchanged. The wireless communication device may encode the transformed bits (e.g., transformed according to the first polar transform 305-a) via the second polar transform 305-b after setting the frozen bit locations to zero and leaving the information and CRC bit locations unchanged. Based on inserting the CRC bits 320 as information bits 315, the CRC bits 320 and the information bits 315 may appear as part of the encoded codeword. For example, after the first polar transform 305-a and a second polar transform 305-b of the systematic polar coding procedure 300, a resulting codeword (e.g., a generated codeword) may include (e.g., transparently) the CRC bits 320 and the information bits 315. In some examples, CRC insertion and polar encoding may be separated at the wireless communication device (e.g., the transmitting device).

A decoder, such as a decoder at a device receiving the codeword generated via the systematic polar coding procedure 300, may perform hard-decision decoding based on a channel condition (e.g., a channel condition threshold). As an example, the decoder may perform hard-decision decoding on the information bits 315 and the CRC bits 320 based on a signal-to-noise ratio (SNR) being above a threshold. The decoder may, in some examples, refrain from performing polar decoding based on the CRC passing (e.g., being successful) during the hard-decision decoding. By refraining from polar decoding, the decoder may conserve power. The decoder may be an example of the systematic polar decoder 220 at the wireless device 205-b as described with reference to FIG. 2.

FIG. 4 shows an example of a systematic polar coding procedure 400 that supports CRC and PC generation for systematic polar coding in accordance with one or more aspects of the present disclosure. The systematic polar coding procedure 400 may implement, or be implemented by, aspects of the wireless communications system 100, the wireless communications system 200, or both. For example, the systematic polar coding procedure 400 may be implemented by a wireless device, such as the wireless device 205-a as described with reference to FIG. 2.

In the example of FIG. 4, a wireless communication device may insert CRC bits 425 after a first polar transform 405-a. For example, the wireless communication device may insert the CRC bits 425 in a second domain (e.g., in a Z domain). As used herein, the first domain (e.g., the U domain) may refer to a domain prior to the first polar transform 405-a. That is, bits in the first domain may refer to bits prior to the first polar transform 405-a (e.g., pre-transformed bits). Additionally, the second domain (e.g., the Z domain) may refer to a domain after the first polar transform 405-a and before the second polar transform 405-b. That is, bits in the second domain may refer to bits in between the first polar transform 405-a and the second polar transform 405-b. In some examples, a third domain (e.g., an X domain) may refer to a domain after both the first polar transform 405-a and the second polar transform 405-b. The wireless communication device may insert the CRC bits 425 such that an input to a second polar transform 405-b satisfies a CRC condition. That is, the CRC bits 425 and the information bits 420 after the first polar transform 405-a (e.g., the transformed information bits) may satisfy the CRC condition. Transformed information bits may refer to bits after the first polar transform 405-a (e.g., in the Z domain) which are mapped to a same location as the information bits 420 prior to the first polar transform 405-a (e.g., in the U domain). For example, the wireless communication device may apply a first polar transform 405-a to information bits 420, such as K information bits. In the example of FIG. 4, a bit sequence u₀, u₁, u_{K-1} may correspond to information bits 420.

To apply the first polar transform 405-a, the wireless communication device may identify bit channels and map the information bits 420 to the identified bit channels. For example, the wireless communication device may determine a reliability level associated with each bit channel of multiple bit channels. As used herein, “bit channels” may refer to or be used interchangeably with “bit locations.” The wireless communication device may determine a polar reliability sequence based on the reliability levels associated with each bit channel. For example, the wireless communication device may order the multiple bit channels from a least reliable bit channel to a most reliable bit channel. Based on the reliability levels, the wireless communication device may identify a first set of bit channels, A, of the multiple bit channels,

$${F}_{2}^{m}$$

(e.g., select A⊂

$${F}_{2}^{m}$$

). For example, the wireless communication device may select the first set of bit channels as bit channels having highest reliability levels according to the polar reliability sequence. The first set of bit channels may include a quantity K+L bit channels, where K may correspond to the quantity of information bits 420 and L may correspond to a quantity of CRC bits 425.

The first set of bit channels may include information bit channels and CRC bit channels (e.g., B⊂A). For example, the wireless communication device may select a first subset (e.g., one or more first bit channels) of the first set of bit channels to be information bit channels and select a second subset (e.g., one or more second bit channels) of the first set of bit channels to be CRC bit channels, where B refers to the CRC bit channels (e.g., to which CRC bits are mapped to) and A refers to the first set of bits channels. The second subset, B, may correspond to a quantity of bit channels having smallest indices according to a natural ordering of indices of the multiple bit channels. In other words, a set B representing a subset of the set A to which CRC bits are to be mapped may include L bit channels (e.g., locations) with smallest indices in the set A. Alternatively, the second subset, B, may correspond to a quantity of bit channels having lowest reliability levels (e.g., according to the polar reliability sequence) in the first set of bit channels. A remaining set of bit channels (e.g., Ā), such as a second set of bit channels, may be frozen bit channels corresponding to frozen bits 410. For example, the second set of bit channels Ā including the frozen bit channels may correspond to bit channels having lowest reliability levels relative to the other bit channels.

The wireless communication device may map the information bits 420 to the first subset of the first set of bit channels corresponding to the information bit channels. For example, the wireless communication device may place the K information bits in A\B (e.g., a subset of A including elements in A that are not in B) prior to the first polar transform 405-a (e.g., in a first domain). Additionally, the wireless communication device may set bits (e.g., zero bits 415 and frozen bits 410, respectively) in the second subset of the first set of bit channels (e.g., corresponding to the CRC bit channels) and in the second set of bit channels (e.g., corresponding to the frozen bit channels) to zero prior to the first polar transform 405-a. In other words, the wireless communication device may set bits in Ā and B to zero.

The wireless communication device may apply the first polar transform 405-a to the bits mapped to the first set of bit channels and the second set of bit channels. For example, the wireless communication device may convert the bits from the first domain (e.g., a U domain) to a second domain (e.g., a Z domain) via the first polar transform 405-a. The bits transformed according to the first polar transform 405-a may be denoted as z.

After the first polar transform 405-a, the wireless communication device may set the bits in the second set of bit channels (e.g., in Ā) to zero (e.g., insert zero bits 415). The bits in the first subset of the first set of bit channels (e.g., in A\B) may be unchanged after the first polar transform 405-a. That is, the bits in z the locations in set A\B after the polar transform are unchanged by the wireless communication device prior to the second polar transform 405-b.

The wireless communication device may generate the CRC bits 425 to be inserted after the first polar transform 405-a and prior to the second polar transform 405-b. For example, the wireless communication device may determine a quantity of CRC bits 425, L, denoted via a bit sequence c₀, . . . , c_{L-1}. The CRC bits 425 and the information bits 420 may satisfy a CRC condition. In other words, a concatenation of the information bits 420 (e.g., z₀, . . . , z_{K-1}) and the CRC bits 425 (e.g., c₀, . . . , c_{L-1}), K+L, may jointly satisfy the CRC condition.

In some examples, satisfying the CRC condition may include generating the CRC bits 425 (e.g., c₀, . . . , c_{L-1}) such that the information bits 420 and the CRC bits 425 (e.g., [z_{K-1}, . . . , z₀, c_{L-1}, . . . , c₀]) satisfy Equation 2 below for a CRC polynomial g*(x), where the information bits 420 and the CRC bits 425 are ordered from last to first.

$${g}^{*} ( x ) = {{x}^{k}}^{} g ( {x}^{- 1} ) \qquad ( 2 )$$

By generating the CRC bits 425 such that Equation 2 is satisfied, the vector [c₀, . . . , c_{L-1}, z₀, . . . , z_{K_1}] may also satisfy the CRC condition as described with reference to Equation 1. In other words, a last L bits of the combined vector (e.g., of the CRC bits 425 and the information bits 420) are the CRC polynomial computed from the first K bits of the combined vector. For example, the CRC bit channels may precede the information bit channels to satisfy the CRC condition.

In some other examples, the wireless communication device may determine the CRC bits 425 such that the CRC bits 425 and the information bits 420 satisfy the CRC condition as described with reference to Equation 1. In other words, the wireless communication device may compute c₀, . . . , c_{L-1} such that [z₀, . . . , z_{K-1}, c₀, . . . , c_{L_1}] satisfies the CRC condition as described with reference to Equation 1. In such examples, the wireless communication device may place the CRC bits 425 on the set B following a natural order of the indices in the set B. A natural order of elements within a set may be defined by an order of a decimal value corresponding to binary vectors (e.g., 0000<0001<0010<0011<0100< . . . <1011<1100<1101<1110<1111). For example, the wireless communication device may insert the CRC bits 425 in an order of a first indexed bit channel to a last indexed bit channel. In other words, c₀, . . . , c_{L_1} represents the L-b it CRC corresponding to the vector z₀, . . . , z_{K_1}.

The wireless communication device may apply the second polar transform 405-b after inserting the CRC bits 425. For example, the wireless communication device may generate a systematic codeword by applying the second polar transform 405-b in which the information bits 420 are transparent. The information bits 420 may be transparent (e.g., the codeword may be systematic) based on locations of the information bits 420 and CRC bits 425 satisfying that both the set A and the set A\B are ∨-closed. In other words, for the resulting codeword to be a systematic polar code, for the information bit channels and for the CRC bit channels, for any element γ, if γ is greater than any element in the set A, γ may also be included in the set A.

A partial order of a first element α may be less than a second element β (e.g., α [symbol] β) in

$${F}_{2}^{m}$$

if αᵢ≤βᵢ, ∀i∈[1, . . . , m], where αᵢ denotes an i-th bit in the binary expansion of α. That is, the first element α may have indices that are less than the second element β according to the partial order if bits in a binary expansion of α are each less than or equal to bits in a binary expansion of β. In such examples, α and β may be length-m binary vectors or a integers between [0,2^{m-1}], where α and β are each elements of a set

$${F}_{2}^{m}$$

(e.g., α,β∈

$${F}_{2}^{m} )$$

A lattice structure may correspond to the partial order, where α∧β may be a lower bound (e.g., a greatest lower bound) of α and β with respect to the partial order [symbol] , and where α∨β may be an upper bound (e.g., a least upper bound) of α and β with respect to the partial order [symbol] . A set A (e.g., A⊂

$${F}_{2}^{m}$$

) may be ∨-closed if α∨β∈A whenever α∧A and β∈

$${F}_{2}^{m}$$

Additionally, or alternatively, the set A may be ∧-closed if α∧β∈A whenever α∈A and β∈

$${F}_{2}^{m}$$

In other words, the set A may be ∧-closed if, for any element γ, γ is smaller than any element in the set A, according to the partial order, then γ may also be included in A.

A decoder, such as a decoder at a device receiving the codeword generated via the systematic polar coding procedure 400, may perform SCL decoding and check CRC in the second domain. For example, the decoder may perform SCL decoding to decode the second polar transform 405-b in which the CRC bits 425 were encoded by the wireless communication device. The decoder may be an example of the systematic polar decoder 220 at the wireless device 205-b as described with reference to FIG. 2.

FIG. 5 shows an example of a systematic polar coding procedure 500 that supports CRC and PC generation for systematic polar coding in accordance with one or more aspects of the present disclosure. The systematic polar coding procedure 500 may implement, or be implemented by, aspects of the wireless communications system 100, the wireless communications system 200, or both. For example, the systematic polar coding procedure 500 may be implemented by a wireless device, such as the wireless device 205-a as described with reference to FIG. 2.

In the example of FIG. 5, a wireless communication device may insert PC bits 525 after a first polar transform 505-a. For example, the wireless communication device may insert the PC bits 525 in a second domain (e.g., in a Z domain). The wireless communication device may insert the PC bits 525 such that an input to a second polar transform 505-b satisfies a PC condition. For example, the wireless communication device may apply a first polar transform 505-a to information bits 520, such as K information bits.

To apply the first polar transform 505-a, the wireless communication device may identify bit channels and map the information bits 520 to the identified bit channels. For example, the wireless communication device may determine a reliability level associated with each bit channel of multiple bit channels. The wireless communication device may determine a polar reliability sequence based on the reliability levels associated with each bit channel. For example, the wireless communication device may order the multiple bit channels from a least reliable bit channel to a most reliable bit channel. Based on the reliability levels, the wireless communication device may identify a first set of bit channels, A, of the multiple bit channels,

$${F}_{2}^{m}$$

(e.g., select A⊂

$${F}_{2}^{m} ) .$$

For example, the wireless communication device may select the first set of bit channels as bit channels having highest reliability levels according to the polar reliability sequence. The first set of bit channels may include a quantity K bit channels, where K may correspond to the quantity of information bits 520. That is, the first set of bit channels, A, may correspond to information bit channels.

The wireless communication device may map the information bits 520 to the first set of bit channels corresponding to the information bit channels. For example, the wireless communication device may place the K information bits in A prior to the first polar transform 505-a (e.g., in a first domain). Additionally, the wireless communication device may set bits in the remaining bit channels to zero (e.g., insert frozen bits 510 or zero bits 515) prior to the first polar transform 505-a. In other words, the wireless communication device may set bits in Ā to zero. The wireless communication device may apply the first polar transform 505-a to the bits mapped to the first set of bit channels. For example, the wireless communication device may convert the bits from the first domain (e.g., a U domain) to a second domain (e.g., a Z domain) via the first polar transform 505-a. The bits transformed according to the first polar transform 505-a may be denoted as z.

The wireless communication device may generate the PC bits 525 to be inserted after the first polar transform 505-a and prior to the second polar transform 505-b. The wireless communication device may determine a second set of bit channels, denoted as C, for the PC bits 525 in accordance with a PC condition. For example, the PC condition may be satisfied based on both the set A and the set A∪C are ∨-closed. The remaining bit channels (e.g., A̅∪̅C̅) may be frozen bit channels (e.g., corresponding to the frozen bits 510). Additionally, the wireless communication device may determine the PC bits 525 based on the value of the transformed bits (e.g., after the first polar transform 505-a) that are mapped to the set A. In other words, the wireless communication device may determine the PC bits 525 based on bits in bit channels corresponding to the information bits 520 after the first polar transform 505-a. A PC bit may be based on transformed information bits in preceding bit channels. For example, the wireless communication device may determine the PC bit in a channel i based on the transformed information bits in bit channels 0 through i−1. After determining the second set of bit channels, the wireless communication device may place the PC bits 525 at the determined bit channels. For example, the wireless communication device may map the PC bits 525 to the second set of bit channels, where the second set of bit channels satisfy the PC condition. After mapping the PC bits 525, the wireless communication device may apply the second polar transform 505-b.

A decoder, such as a decoder at a device receiving the codeword generated via the systematic polar coding procedure 500, may use a conventional decoder associated with a PC polar code (e.g., a non-systematic PC polar code) to decode bits transformed via the first polar transform 505-a (e.g., in the Z domain). The decoder may extract the transformed information bits (e.g., in the Z domain) from the first set of bit channels, A, (e.g., information bit channels) and apply an inverse of the first polar transform 505-a (e.g., invert the first polar transform 505-a) to obtain the information bits 520 (e.g., untransformed, in the U domain).

Alternatively, after decoding the bits transformed via the first polar transform 505-a (e.g., in the Z domain), the decoder may apply the second polar transform 505-b on the transformed bits to obtain the information bits 520 (e.g., in the X domain). That is, because the systematic polar coding procedure 500 is systematic, the decoder may obtain the information bits 520 from bits transformed via the first polar transform 505-a and the second polar transform 505-b or from the pre-transformed bits.

In some implementations, the wireless communication device may combine the systematic polar coding procedure 500 with one of the systematic polar coding procedure 300 or the systematic polar coding procedure 400. For example, the wireless communication device may include, in addition to the PC bits 525, CRC bits. The wireless communication device may insert the CRC bits prior to the first polar transform 505-a (e.g., as described with reference to FIG. 3) or after the first polar transform 505-a (e.g., as described with reference to FIG. 4).

In the example of inserting CRC bits prior to the first polar transform 505-a, the first set of bit channels described with reference to FIG. 5 may additionally include CRC bits. For example, the first set of bit channels, A, may include the information bits 520 and one or more CRC bits. The wireless communication device may determine the CRC bits based on a CRC condition, such as the CRC condition described with reference to FIG. 3. In such examples, because the PC bits 525 in the example of FIG. 5 are based on the information bits 520 (e.g., based on the first set of bit channels), the PC bits 525 may additionally be based on the CRC bits. For example, the wireless communication device may select the PC bits 525 based on satisfying the PC condition that both A (e.g., including both the information bits 520 and the CRC bits) and A∪C are ∨-closed.

In the example of inserting CRC bits after the first polar transform 505-a, the wireless communication device may select the first set of bit channels, A, according to a quantity of the information bits 520, K, and a quantity of the CRC bits, L. For example, the wireless communication device may select the first set of bit channels as the K+L bit channels having a highest reliability level according to a polar reliability sequence. The wireless communication device may select a subset of the first set of bit channels, B⊂A to be the L bit locations with smallest indices in A. Alternatively, the wireless communication device may select the subset of the first set of bit channels, B, such that the set A\B and A are both ∨-closed. After the first polar transform 505-a, the wireless communication device may determine the CRC bits in B such that the information bits 520 and the CRC bits satisfy a CRC condition (e.g., such that z_{A\B} and z_{B} satisfy the CRC condition). For example, the wireless communication device may determine the CRC bits in accordance with the CRC condition described with reference to FIG. 4. Additionally, the wireless communication device may place the PC bits 525 in the second set of bit channels, C, such that the PC bits 525 and the information bits 520 satisfy the PC condition (e.g., such that z_{C} and z_{A} satisfy the PC condition). The wireless communication device may set the remaining bits (e.g., A̅∪̅C̅) to zero.

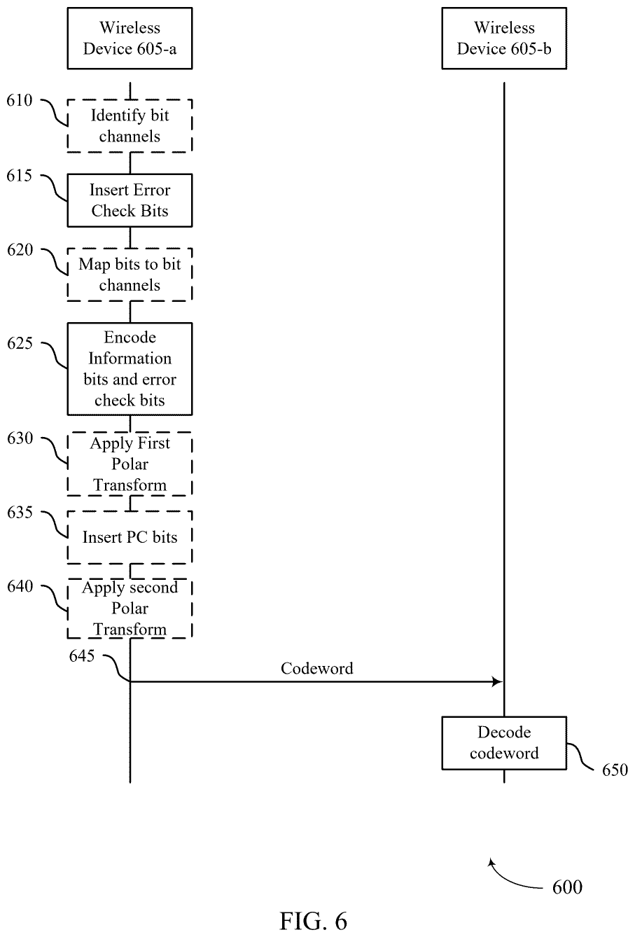

FIG. 6 shows an example of a process flow 600 that supports CRC and PC generation for systematic polar coding in accordance with one or more aspects of the present disclosure. The process flow 600 may implement, or be implemented by, aspects of the wireless communications system 100, the wireless communications system 200, the systematic polar coding procedure 300, the systematic polar coding procedure 400, or the systematic polar coding procedure 500. For example, the process flow 600 may include a wireless device 605-a and a wireless device 605-b, which may be examples of the wireless device 205-a or the wireless device 205-b as described with reference to FIG. 2.

In the following description of the process flow 600, the operations between the wireless device 605-a and the wireless device 605-b may occur in a different order than the example order shown, or the operations performed by the wireless device 605-a and the wireless device 605-b may be performed in different orders or at different times. Some operations may also be omitted from the process flow 600, and other operations may be added to the process flow 600.

At 610, the wireless device 605-a may identify bit channels. For example, the wireless device 605-a may identify a first set of bit channels from multiple bit channels based on a respective reliability level for each bit channel of the multiple bit channels. The first set of bit channels may include one or more information bit channels, and a second set of bit channels of the multiple bit channels (e.g., separate from the first set of bit channels) may include one or more frozen bit channels. The first set of bit channels may include bit channels having higher reliability levels (e.g., according to a polar reliability sequence) than the second set of bit channels.

At 615, the wireless device 605-a may insert error check bits. For example, the wireless device 605-a may insert one or more error check bits into multiple information bits prior to a first polar transform of a systematic polar coding procedure on the multiple information bits. The error check bits may be an example of CRC bits, such as the CRC bits 320 as described with reference to FIG. 3. For example, the process flow 600 may illustrate and describe a systematic polar coding procedure similar to the systematic polar coding procedure 300 where the CRC bits are inserted into the information bits prior to the first polar transform.

At 620, the wireless device 605-a may map bits to bit channels. For example, the wireless device 605-a may map the multiple information bits and the one or more error check bits to the first set of bit channels. The wireless device 605-a may map the bits at 620 based on identifying the bit channels at 610. The wireless device 605-a may map the information bits and the error check bits such that locations of the information bits and the error check bits (e.g., a sum of the locations) satisfy a condition, such as a CRC condition. For example, a codeword generated via the systematic polar coding procedure may be systematic (e.g., transparently include the information bits) based on the condition being satisfied.

At 625, the wireless device 605-a may encode information bits and error check bits. For example, the wireless device 605-a may encode the multiple information bits and the one or more error check bits to generate a codeword. The encoding may include the first polar transform and a second polar transform of the systematic polar coding procedure. For example, at 630, the wireless device 605-a may apply the first polar transform, and at 640, the wireless device 605-a may apply the second polar transform. The codeword may include the multiple information bits and the one or more error check bits (e.g., transparently). For example, based on the information bits and the error check bits being inserted prior to the first polar transform and the condition being satisfied at 620, the codeword may include the bits transparently. In other words, encoding the multiple information bits and the one or more error check bits at 625 may be based on the mapping at 620.

At 635 (e.g., prior to the second polar transform at 640), the wireless device 605-a may insert PC bits. For example, the one or more error check bits may include one or more CRC bits that are based on the multiple information bits, and the wireless device 605-a may additionally insert PC bits. That is, the wireless device 605-a may insert one or more PC bits after the first polar transform at 630 and prior to the second polar transform at 640 of the systematic polar coding procedure, where the one or more PC bits are determined based on the multiple information bits and the one or more CRC bits. In such examples, respective values of the one or more PC bits may be based on information bits of the multiple information bits at bit channels after the first polar transform at 630 having lower indices than an index of a respective PC bit of the one or more PC bits.

At 645, the wireless device 605-a may output a codeword. For example, the wireless device 605-a may output the codeword based on the encoding at 625. At 650, the wireless device 605-b may decode the codeword. For example, the wireless device 605-b may decode the codeword via (e.g., using, by applying, or the like) a systematic polar decoder, such as the systematic polar decoder 220 as described with reference to FIG. 2. Decoding the codeword via the systematic polar decoder may involve a systematic polar decoding procedure in which the wireless device 605-b performs one or more polar transforms to decode the codeword. For example, the wireless device 605-b may perform the second polar coding transform on the bits of the codeword, and then perform the first polar coding transform to identify the bits inserted to one or more bit channels (e.g., originally). In other words, the systematic polar decoding procedure may correspond to a reverse order of one or more operations in the systematic polar encoding procedure.

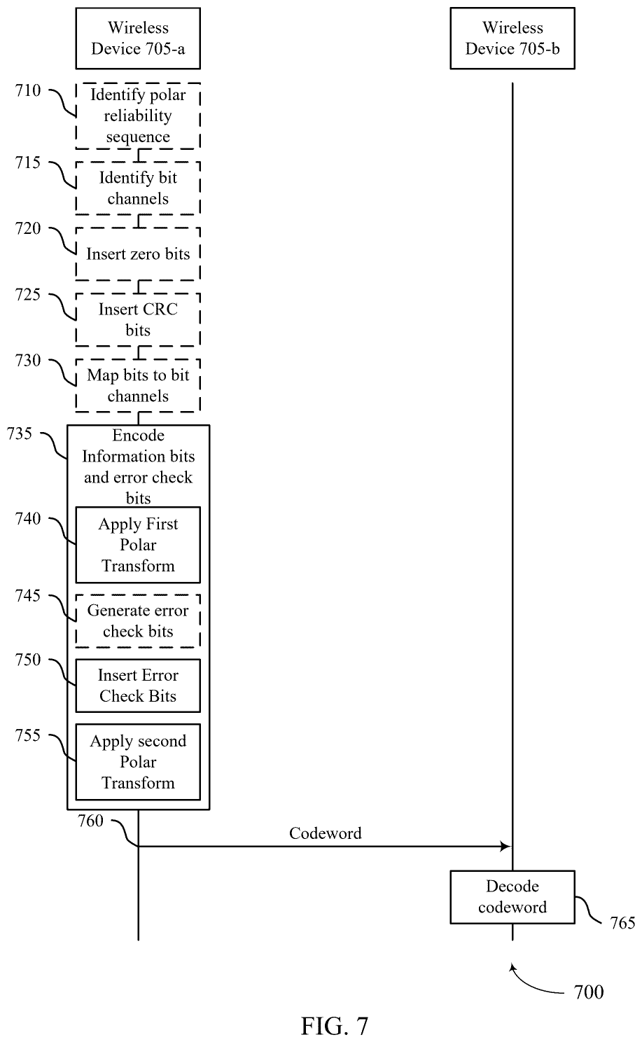

FIG. 7 shows an example of a process flow 700 that supports CRC and PC generation for systematic polar coding in accordance with one or more aspects of the present disclosure. The process flow 700 may implement, or be implemented by, aspects of the wireless communications system 100, the wireless communications system 200, the systematic polar coding procedure 300, the systematic polar coding procedure 400, or the systematic polar coding procedure 500. For example, the process flow 700 may include a wireless device 705-a and a wireless device 705-b, which may be examples of the wireless device 205-a or the wireless device 205-b as described with reference to FIG. 2.

In the following description of the process flow 700, the operations between the wireless device 705-a and the wireless device 705-b may occur in a different order than the example order shown, or the operations performed by the wireless device 705-a and the wireless device 705-b may be performed in different orders or at different times. Some operations may also be omitted from the process flow 700, and other operations may be added to the process flow 700.

At 710, the wireless device 705-a may identify a polar reliability sequence. For example, the wireless device 705-a may identify a polar reliability sequence that orders the respective reliability level for each bit channel of multiple bit channels. That is, the polar reliability sequence may order the bit channels from least reliable to most reliable.

At 715, the wireless device 705-a may identify bit channels. For example, the wireless device 705-a may identify a first set of bit channels from the multiple bit channels based on a respective reliability level for each bit channel of the multiple bit channels. The first set of bit channels may include one or more first bit channels (e.g., information bit channels), and a second set of bit channels of the multiple bit channels may include frozen bit channels. For example, the first set of bit channels may include bit channels having a higher reliability level than the bit channels included in the second set of bit channels.

In some examples, the wireless device 705-a may identify a third set of bit channels from the multiple bit channels. For example, the third set of bit channels may include PC bit channels. In such examples, respective values of one or more PC bits may be based on information bits of the multiple information bits at bit channels after the first polar transform at 740 with lower indices than an index of a respective PC bit of the one or more PC bits. In other words, respective PC bits may be based on prior information bits.

At 720, the wireless device 705-a may insert zero bits. For example, the wireless device 705-a may insert one or more bits having bit values of zero into one or more second bit channels of the first set of bit channels prior to the first polar transform at 740. Such second bit channels of the first set of bit channels may correspond to channels to be used for error check bits, where the error check bits are mapped to the second bit channels after the first polar transform at 740. In other words, the wireless device 705-a may insert zero for channels corresponding to error check channels (e.g., CRC channels) prior to the first polar transform at 740.

At 725, the wireless device 705-a may insert CRC bits. For example, the wireless device 705-a may insert one or more CRC bits into the multiple information bits prior to the first polar transform at 740, where the one or more CRC bits are determined based on the multiple information bits. That is, the wireless device 705-a may determine the CRC bits in accordance with the CRC bits and the information bits satisfying a constraint. The constraint may be described in greater detail elsewhere herein, including with reference to FIG. 3.

At 730, the wireless device 705-a may map bits to channels. For example, the wireless device 705-a may map the multiple information bits to the first set of bit channels identified at 715. At 735, the wireless device 705-a may encode information bits and error check bits. For example, the wireless device 705-a may encode the multiple information bits and one or more error check bits via a first polar transform and a second polar transform of a systematic polar coding procedure to generate a codeword. The systematic polar coding procedure may be an example of the systematic polar coding procedure 400 or the systematic polar coding procedure 500 as described with reference to FIGS. 4 and 5.

The encoding may include, at 740, applying the first polar transform. For example, the wireless device 705-a may apply the first polar transform to the multiple information bits. Encoding the information bits via the first polar transform may be based on the mapping at 730. In examples in which the wireless device 705-a inserts the CRC bits at 725, the wireless device 705-a may apply the first polar transform to the multiple information bits including the CRC bits.

At 745, the wireless device 705-a may generate error check bits. For example, the wireless device 705-a may generate the one or more error check bits, where the one or more error check bits include one or more CRC bits. In examples in which the one or more error check bits include the one or more CRC bits, the wireless device 705-a may determine the one or more error check bits in accordance with a CRC code associated with a CRC condition. For example, the one or more error check bits and the multiple information bits may satisfy the CRC condition. The CRC condition may correspond to the CRC conditions discussed with reference to FIG. 4. Additionally, or alternatively, the one or more error check bits may include one or more PC bits. In such examples, the wireless device 705-a may determine the one or more error check bits in accordance with a PC condition, such as the PC condition described with reference to FIG. 5.

At 750, the wireless device 705-a may insert error check bits. For example, the wireless device 705-a may insert the one or more error check bits after the first polar transform at 740 and prior to the second polar transform at 755. In some examples, the wireless device 705-a may insert the one or more error check bits into one or more second bit channels of the first set of bit channels. That is, the wireless device 705-a may insert the one or more error check bits into a subset of bit channels of a set of information bit channels. The one or more second bit channels may precede the one or more first bit channels comprising the multiple information bits (e.g., within the first set of bit channels). Additionally, or alternatively, the wireless device 705-a may insert the one or more error check bits in an order of a first indexed bit channel to a last indexed bit channel of the one or more second bit channels. In examples in which the one or more error check bits include PC bits, the PC bits may satisfy a PC relationship (e.g., a PC condition), such as a PC relationship in which respective PC bits are based on preceding information bits. In examples in which the one or more error check bits include PC bits in addition to CRC bits, the wireless device 705-a may determine the PC bits based on the information bits and the CRC bits. For example, a quantity of the PC bits may satisfy a PC relationship (e.g., where the PC bits are based on preceding information bits, including preceding CRC bits).

At 755, the wireless device 705-a may apply the second polar transform. For example, the wireless device 705-a may apply the second polar transform after inserting the one or more error check bits at 750. After applying the second polar transform, at 760, the wireless device 705-a may output the codeword. For example, the wireless device 705-a may output the codeword based on the encoding via the first polar transform and the second polar transform, where the codeword includes the plurality of information bits (e.g., transparently). In some examples, the codeword may include the multiple information bits based on the information bit channels, the error check bit channels, or both satisfying a condition. For example, for a first set including the first set of bit channels (e.g., information bit channels) and for a second set including the third set of bit channels (e.g., PC bit channels), the condition may be that one or more indices that are larger than a respective element of multiple elements of a set, based on a partial ordering, are included in the set.

At 765, the wireless device 705-b may decode the codeword. For example, the wireless device 705-b may decode the codeword via (e.g., using, by applying, or the like) a systematic polar decoder, such as the systematic polar decoder 220 as described with reference to FIG. 2. Decoding the codeword via the systematic polar decoder may involve a systematic polar decoding procedure in which the wireless device 705-b performs one or more polar transforms to decode the codeword. For example, the wireless device 705-b may perform the second polar coding transform on the bits of the codeword, and then perform the first polar coding transform to identify the bits inserted to one or more bit channels (e.g., originally). In other words, the systematic polar decoding procedure may correspond to a reverse order of one or more operations in the systematic polar encoding procedure.

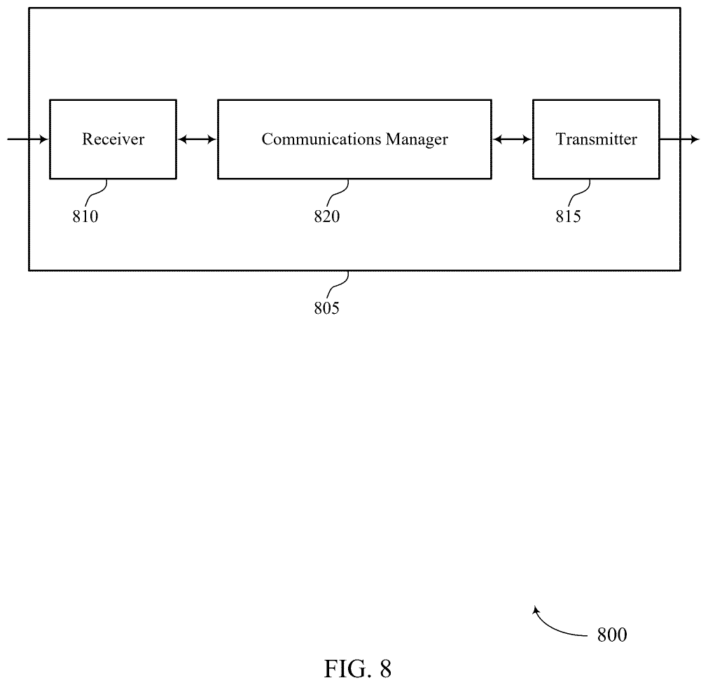

FIG. 8 shows a block diagram 800 of a device 805 that supports CRC and PC generation for systematic polar coding in accordance with one or more aspects of the present disclosure. The device 805 may be an example of aspects of a network entity 105 or a UE 115 as described herein. The device 805 may include a receiver 810, a transmitter 815, and a communications manager 820. The device 805, or one or more components of the device 805 (e.g., the receiver 810, the transmitter 815, the communications manager 820), may include at least one processor, which may be coupled with at least one memory, to, individually or collectively, support or enable the described techniques. Each of these components may be in communication with one another (e.g., via one or more buses).

The receiver 810 may provide a means for obtaining (e.g., receiving, determining, identifying) information such as user data, control information, or any combination thereof (e.g., I/Q samples, symbols, packets, protocol data units, service data units) associated with various channels (e.g., control channels, data channels, information channels, channels associated with a protocol stack). Information may be passed on to other components of the device 805. In some examples, the receiver 810 may support obtaining information by receiving signals via one or more antennas. Additionally, or alternatively, the receiver 810 may support obtaining information by receiving signals via one or more wired (e.g., electrical, fiber optic) interfaces, wireless interfaces, or any combination thereof.

The transmitter 815 may provide a means for outputting (e.g., transmitting, providing, conveying, sending) information generated by other components of the device 805. For example, the transmitter 815 may output information such as user data, control information, or any combination thereof (e.g., I/Q samples, symbols, packets, protocol data units, service data units) associated with various channels (e.g., control channels, data channels, information channels, channels associated with a protocol stack). In some examples, the transmitter 815 may support outputting information by transmitting signals via one or more antennas. Additionally, or alternatively, the transmitter 815 may support outputting information by transmitting signals via one or more wired (e.g., electrical, fiber optic) interfaces, wireless interfaces, or any combination thereof. In some examples, the transmitter 815 and the receiver 810 may be co-located in a transceiver, which may include or be coupled with a modem.

The communications manager 820, the receiver 810, the transmitter 815, or various combinations or components thereof may be examples of means for performing various aspects of CRC and PC generation for systematic polar coding as described herein. For example, the communications manager 820, the receiver 810, the transmitter 815, or various combinations or components thereof may be capable of performing one or more of the functions described herein.

In some examples, the communications manager 820, the receiver 810, the transmitter 815, or various combinations or components thereof may be implemented in hardware (e.g., in communications management circuitry). The hardware may include at least one of a processor, a DSP, a CPU, an ASIC, an FPGA or other programmable logic device, a microcontroller, discrete gate or transistor logic, discrete hardware components, or any combination thereof configured as or otherwise supporting, individually or collectively, a means for performing the functions described in the present disclosure. In some examples, at least one processor and at least one memory coupled with the at least one processor may be configured to perform one or more of the functions described herein (e.g., by one or more processors, individually or collectively, executing instructions stored in the at least one memory).

Additionally, or alternatively, the communications manager 820, the receiver 810, the transmitter 815, or various combinations or components thereof may be implemented in code (e.g., as communications management software or firmware) executed by at least one processor (e.g., referred to as a processor-executable code). If implemented in code executed by at least one processor, the functions of the communications manager 820, the receiver 810, the transmitter 815, or various combinations or components thereof may be performed by a general-purpose processor, a DSP, a CPU, an ASIC, an FPGA, a microcontroller, or any combination of these or other programmable logic devices (e.g., configured as or otherwise supporting, individually or collectively, a means for performing the functions described in the present disclosure).

In some examples, the communications manager 820 may be configured to perform various operations (e.g., receiving, obtaining, monitoring, outputting, transmitting) using or otherwise in cooperation with the receiver 810, the transmitter 815, or both. For example, the communications manager 820 may receive information from the receiver 810, send information to the transmitter 815, or be integrated in combination with the receiver 810, the transmitter 815, or both to obtain information, output information, or perform various other operations as described herein.

The communications manager 820 may support wireless communications in accordance with examples as disclosed herein. For example, the communications manager 820 is capable of, configured to, or operable to support a means for inserting one or more error check bits into a set of multiple information bits, where the one or more error check bits are inserted prior to a first polar transform of a systematic polar coding procedure on the set of multiple information bits. The communications manager 820 is capable of, configured to, or operable to support a means for encoding the set of multiple information bits and the one or more error check bits to generate a codeword via the first polar transform and a second polar transform in accordance with the systematic polar coding procedure, where the codeword includes the set of multiple information bits and the one or more error check bits. The communications manager 820 is capable of, configured to, or operable to support a means for outputting the codeword based on the encoding.

Additionally, or alternatively, the communications manager 820 may support wireless communications in accordance with examples as disclosed herein. For example, the communications manager 820 is capable of, configured to, or operable to support a means for encoding a set of multiple information bits and one or more error check bits via a first polar transform and a second polar transform of a systematic polar coding procedure to generate a codeword. In some examples, to the encode, the communications manager 820 may be configured as or otherwise support a means for applying the first polar transform to the set of multiple information bits and inserting the one or more error check bits after the first polar transform and prior to the second polar transform. The communications manager 820 is capable of, configured to, or operable to support a means for outputting the codeword based on the encoding via the first polar transform and the second polar transform, where the codeword includes the set of multiple information bits.

By including or configuring the communications manager 820 in accordance with examples as described herein, the device 805 (e.g., at least one processor controlling or otherwise coupled with the receiver 810, the transmitter 815, the communications manager 820, or a combination thereof) may support techniques for reduced complexity related to an encoding structure and improved performance related to a bit error rate.

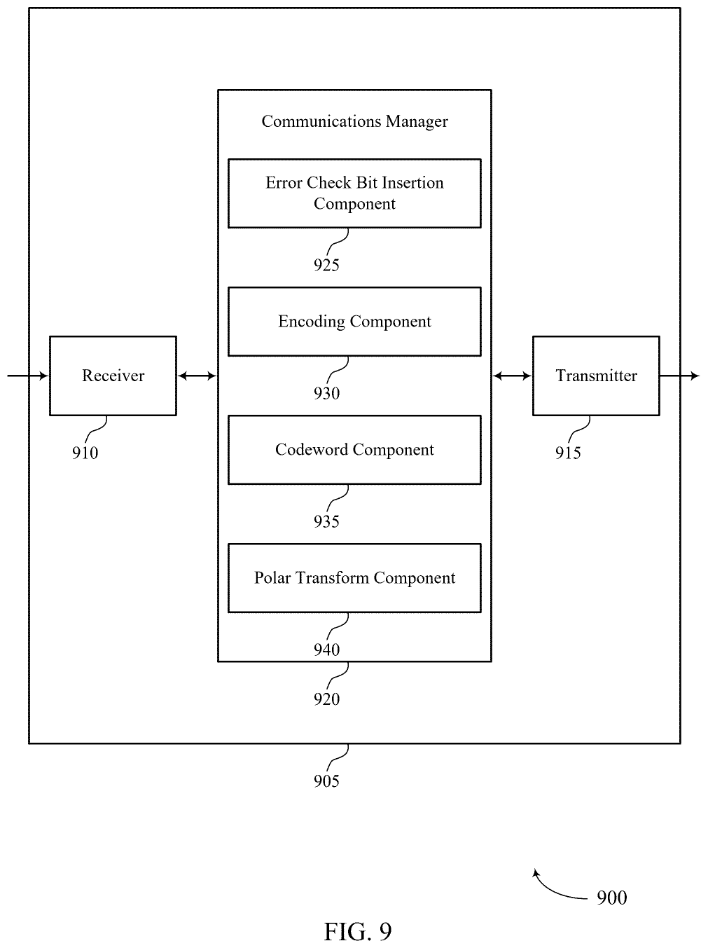

FIG. 9 shows a block diagram 900 of a device 905 that supports CRC and PC generation for systematic polar coding in accordance with one or more aspects of the present disclosure. The device 905 may be an example of aspects of a device 805 or a network entity 105 or a UE 115 as described herein. The device 905 may include a receiver 910, a transmitter 915, and a communications manager 920. The device 905, or one or more components of the device 905 (e.g., the receiver 910, the transmitter 915, the communications manager 920), may include at least one processor, which may be coupled with at least one memory, to support the described techniques. Each of these components may be in communication with one another (e.g., via one or more buses).

The receiver 910 may provide a means for obtaining (e.g., receiving, determining, identifying) information such as user data, control information, or any combination thereof (e.g., I/Q samples, symbols, packets, protocol data units, service data units) associated with various channels (e.g., control channels, data channels, information channels, channels associated with a protocol stack). Information may be passed on to other components of the device 905. In some examples, the receiver 910 may support obtaining information by receiving signals via one or more antennas. Additionally, or alternatively, the receiver 910 may support obtaining information by receiving signals via one or more wired (e.g., electrical, fiber optic) interfaces, wireless interfaces, or any combination thereof.

The transmitter 915 may provide a means for outputting (e.g., transmitting, providing, conveying, sending) information generated by other components of the device 905. For example, the transmitter 915 may output information such as user data, control information, or any combination thereof (e.g., I/Q samples, symbols, packets, protocol data units, service data units) associated with various channels (e.g., control channels, data channels, information channels, channels associated with a protocol stack). In some examples, the transmitter 915 may support outputting information by transmitting signals via one or more antennas. Additionally, or alternatively, the transmitter 915 may support outputting information by transmitting signals via one or more wired (e.g., electrical, fiber optic) interfaces, wireless interfaces, or any combination thereof. In some examples, the transmitter 915 and the receiver 910 may be co-located in a transceiver, which may include or be coupled with a modem.

The device 905, or various components thereof, may be an example of means for performing various aspects of CRC and PC generation for systematic polar coding as described herein. For example, the communications manager 920 may include an error check bit insertion component 925, an encoding component 930, a codeword component 935, or any combination thereof. The communications manager 920 may be an example of aspects of a communications manager 820 as described herein. In some examples, the communications manager 920, or various components thereof, may be configured to perform various operations (e.g., receiving, obtaining, monitoring, outputting, transmitting) using or otherwise in cooperation with the receiver 910, the transmitter 915, or both. For example, the communications manager 920 may receive information from the receiver 910, send information to the transmitter 915, or be integrated in combination with the receiver 910, the transmitter 915, or both to obtain information, output information, or perform various other operations as described herein.

The communications manager 920 may support wireless communications in accordance with examples as disclosed herein. The error check bit insertion component 925 is capable of, configured to, or operable to support a means for inserting one or more error check bits into a set of multiple information bits, where the one or more error check bits are inserted prior to a first polar transform of a systematic polar coding procedure on the set of multiple information bits. The encoding component 930 is capable of, configured to, or operable to support a means for encoding the set of multiple information bits and the one or more error check bits to generate a codeword via the first polar transform and a second polar transform in accordance with the systematic polar coding procedure, where the codeword includes the set of multiple information bits and the one or more error check bits. The codeword component 935 is capable of, configured to, or operable to support a means for outputting the codeword based on the encoding.

Additionally, or alternatively, the communications manager 920 may support wireless communications in accordance with examples as disclosed herein. The encoding component 930 is capable of, configured to, or operable to support a means for encoding a set of multiple information bits and one or more error check bits via a first polar transform and a second polar transform of a systematic polar coding procedure to generate a codeword. In some examples, to the encode, the polar transform component 940 may be configured as or otherwise support a means for applying the first polar transform to the set of multiple information bits and the error check bit insertion component 925 may be configured as or otherwise support a means for inserting the one or more error check bits after the first polar transform and prior to the second polar transform. The codeword component 935 is capable of, configured to, or operable to support a means for outputting the codeword based on the encoding via the first polar transform and the second polar transform, where the codeword includes the set of multiple information bits.

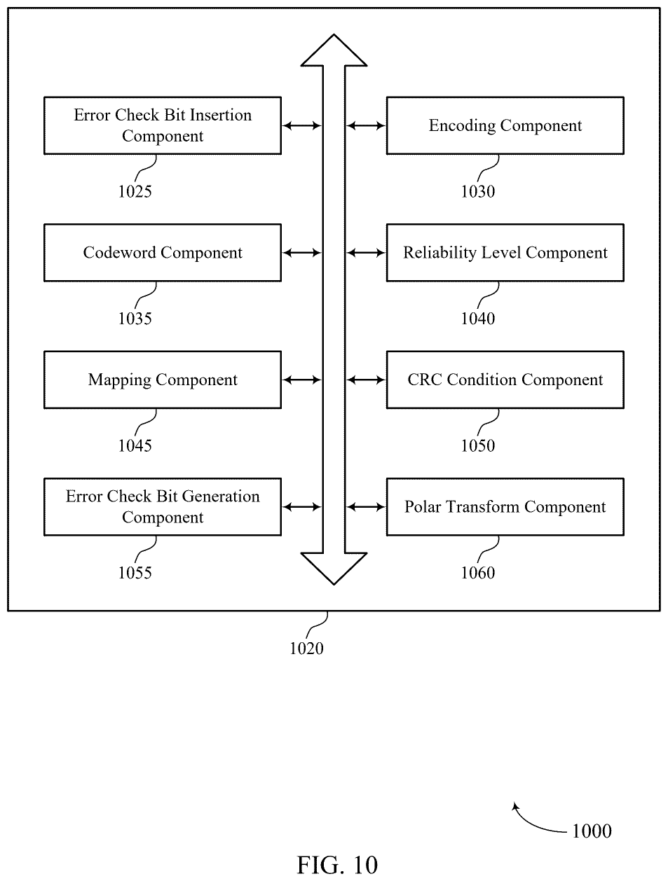

FIG. 10 shows a block diagram 1000 of a communications manager 1020 that supports CRC and PC generation for systematic polar coding in accordance with one or more aspects of the present disclosure. The communications manager 1020 may be an example of aspects of a communications manager 820, a communications manager 920, or both, as described herein. The communications manager 1020, or various components thereof, may be an example of means for performing various aspects of CRC and PC generation for systematic polar coding as described herein. For example, the communications manager 1020 may include an error check bit insertion component 1025, an encoding component 1030, a codeword component 1035, a reliability level component 1040, a mapping component 1045, an CRC condition component 1050, an error check bit generation component 1055, a polar transform component 1060, or any combination thereof. Each of these components, or components or subcomponents thereof (e.g., one or more processors, one or more memories), may communicate, directly or indirectly, with one another (e.g., via one or more buses). The communications may include communications within a protocol layer of a protocol stack, communications associated with a logical channel of a protocol stack (e.g., between protocol layers of a protocol stack, within a device, component, or virtualized component associated with a network entity 105, between devices, components, or virtualized components associated with a network entity 105), or any combination thereof.

The communications manager 1020 may support wireless communications in accordance with examples as disclosed herein. The error check bit insertion component 1025 is capable of, configured to, or operable to support a means for inserting one or more error check bits into a set of multiple information bits, where the one or more error check bits are inserted prior to a first polar transform of a systematic polar coding procedure on the set of multiple information bits. The encoding component 1030 is capable of, configured to, or operable to support a means for encoding the set of multiple information bits and the one or more error check bits to generate a codeword via the first polar transform and a second polar transform in accordance with the systematic polar coding procedure, where the codeword includes the set of multiple information bits and the one or more error check bits. The codeword component 1035 is capable of, configured to, or operable to support a means for outputting the codeword based on the encoding.

In some examples, the reliability level component 1040 is capable of, configured to, or operable to support a means for identifying a first set of bit channels from a set of multiple bit channels based on a respective reliability level for each bit channel of the set of multiple bit channels, the first set of bit channels including one or more information bit channels, where a second set of bit channels of the set of multiple bit channels include one or more frozen bit channels. In some examples, the mapping component 1045 is capable of, configured to, or operable to support a means for mapping the set of multiple information bits and the one or more error check bits to the first set of bit channels, where encoding the set of multiple information bits and the one or more error check bits is based on the mapping.

In some examples, the one or more error check bits include one or more CRC bits that are based on the set of multiple information bits, and the error check bit insertion component 1025 is capable of, configured to, or operable to support a means for inserting one or more PC bits after the first polar transform and prior to the second polar transform of the systematic polar coding procedure, where the one or more PC bits are determined based on the set of multiple information bits and the one or more CRC bits.

In some examples, respective values of the one or more PC bits are based on information bits of the set of multiple information bits at bit channels after the first polar transform having lower indices than an index of a respective PC bit of the one or more PC bits.

Additionally, or alternatively, the communications manager 1020 may support wireless communications in accordance with examples as disclosed herein. In some examples, the encoding component 1030 is capable of, configured to, or operable to support a means for encoding a set of multiple information bits and one or more error check bits via a first polar transform and a second polar transform of a systematic polar coding procedure to generate a codeword. In some examples, to the encode, the polar transform component 1060 is capable of, configured to, or operable to support a means for applying the first polar transform to the set of multiple information bits and the error check bit insertion component 1025 is capable of, configured to, or operable to support a means for inserting the one or more error check bits after the first polar transform and prior to the second polar transform. In some examples, the codeword component 1035 is capable of, configured to, or operable to support a means for outputting the codeword based on the encoding via the first polar transform and the second polar transform, where the codeword includes the set of multiple information bits.

In some examples, the reliability level component 1040 is capable of, configured to, or operable to support a means for identifying a first set of bit channels from a set of multiple bit channels based on a respective reliability level for each bit channel of the set of multiple bit channels, the first set of bit channels including one or more first bit channels including information bit channels, where a second set of bit channels of the set of multiple bit channels include frozen bit channels. In some examples, the mapping component 1045 is capable of, configured to, or operable to support a means for mapping the set of multiple information bits to the first set of bit channels, where encoding the set of multiple information bits via the first polar transform is based on the mapping.

In some examples, the error check bit insertion component 1025 is capable of, configured to, or operable to support a means for inserting one or more bits having bit values of zero into one or more second bit channels of the first set of bit channels prior to the first polar transform.

In some examples, to support inserting the one or more error check bits, the error check bit insertion component 1025 is capable of, configured to, or operable to support a means for inserting the one or more error check bits into one or more second bit channels of the first set of bit channels.

In some examples, the error check bit generation component 1055 is capable of, configured to, or operable to support a means for generating the one or more error check bits, where the one or more error check bits include one or more CRC bits, and where inserting the one or more CRC bits further includes inserting the one or more CRC bits into the one or more second bit channels, where the one or more second bit channels precede the one or more first bit channels including the set of multiple information bits.

In some examples, the reliability level component 1040 is capable of, configured to, or operable to support a means for identifying a polar reliability sequence that orders the respective reliability level for each bit channel of the set of multiple bit channels, where identifying the first set of bit channels is based on identifying the polar reliability sequence.

In some examples, the codeword includes the set of multiple information bits based on the first set of bit channels and the one or more first bit channels satisfying a condition.

In some examples, for a first set including the first set of bit channels and for a second set including the second set of bit channels, the condition includes that one or more indices that are larger than a respective element of a set of multiple elements of a set, based on a partial ordering, are included in the set.

In some examples, the CRC condition component 1050 is capable of, configured to, or operable to support a means for determine the one or more error check bits in accordance with a CRC code associated with a CRC condition, where the one or more error check bits and the set of multiple information bits satisfy the CRC condition, and where inserting the one or more error check bits is based on determining the one or more error check bits.

In some examples, the error check bit generation component 1055 is capable of, configured to, or operable to support a means for generating the one or more error check bits in accordance with a CRC condition, where inserting the one or more error check bits further includes inserting the one or more error check bits into one or more second bit channels of a first set of bit channels, where the one or more error check bits are inserted in an order of a first indexed bit channel to a last indexed bit channel of the one or more second bit channels.

In some examples, the reliability level component 1040 is capable of, configured to, or operable to support a means for identifying a first set of bit channels from a set of multiple bit channels based on a respective reliability level for each bit channel of the set of multiple bit channels, the first set of bit channels including information bit channels. In some examples, the reliability level component 1040 is capable of, configured to, or operable to support a means for identifying a second set of bit channels from the set of multiple bit channels, the second set of bit channels including PC bit channels. In some examples, the reliability level component 1040 is capable of, configured to, or operable to support a means for identifying a third set of bit channels of the set of multiple bit channels, the third set of bit channels including frozen bit channels. In some examples, the mapping component 1045 is capable of, configured to, or operable to support a means for mapping the set of multiple information bits to the first set of bit channels, where encoding the set of multiple information bits via the first polar transform is based on the mapping.

In some examples, to support inserting the one or more error check bits, the error check bit insertion component 1025 is capable of, configured to, or operable to support a means for inserting the one or more error check bits into the second set of bit channels.

In some examples, respective values of one or more PC bits are based on information bits of the set of multiple information bits at bit channels after the first polar transform with lower indices than an index of a respective PC bit of the one or more PC bits.

In some examples, the one or more error check bits include one or more CRC bits or one or more PC bits.

In some examples, the error check bit insertion component 1025 is capable of, configured to, or operable to support a means for inserting one or more CRC bits into the set of multiple information bits prior to the first polar transform, where the one or more CRC bits are determined based on the set of multiple information bits. In some examples, the error check bit insertion component 1025 is capable of, configured to, or operable to support a means for inserting the one or more error check bits after the first polar transform and prior to the second polar transform of the systematic polar coding procedure, where the one or more error check bits include one or more PC bits, and where the one or more PC bits are determined based on the set of multiple information bits and the one or more error check bits.

In some examples, the one or more error check bits include one or more CRC bits and one or more PC bits, and the error check bit insertion component 1025 is capable of, configured to, or operable to support a means for inserting the one or more CRC bits after the first polar transform and prior to the second polar transform of the systematic polar coding procedure, where a first quantity of the one or more CRC bits satisfies a CRC condition. In some examples, the one or more error check bits include one or more CRC bits and one or more PC bits, and the error check bit insertion component 1025 is capable of, configured to, or operable to support a means for inserting the one or more PC bits after the first polar transform and prior to the second polar transform of the systematic polar coding procedure, where a second quantity of the one or more PC bits satisfies a PC relationship.

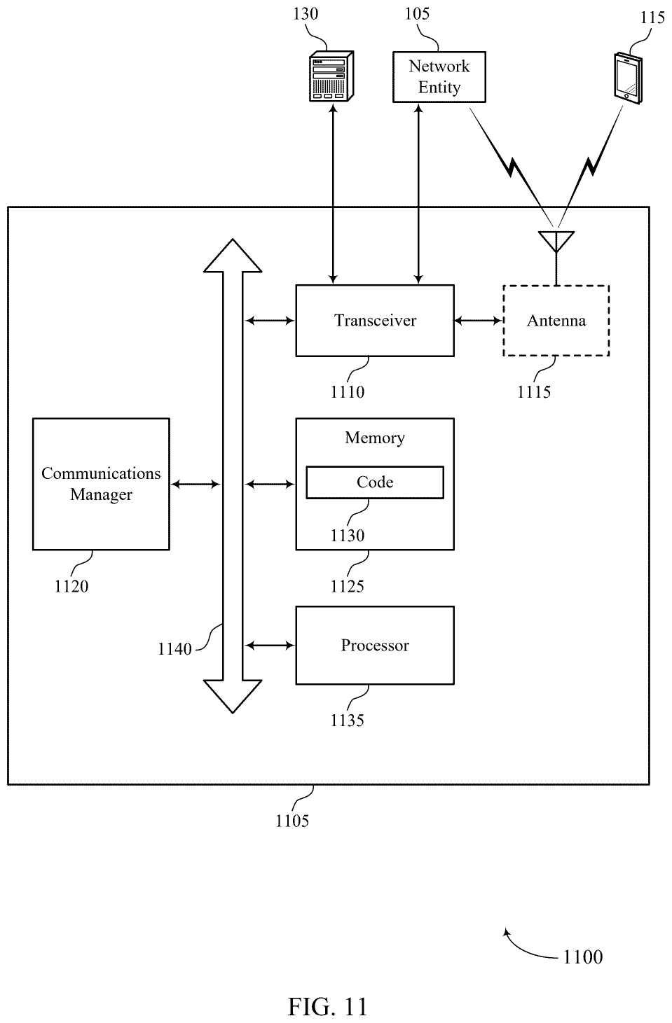

FIG. 11 shows a diagram of a system 1100 including a device 1105 that supports CRC and PC generation for systematic polar coding in accordance with one or more aspects of the present disclosure. The device 1105 may be an example of or include components of a device 805, a device 905, a network entity 105, or a UE 115 as described herein. The device 1105 may communicate with other network devices or network equipment such as one or more of the network entities 105, UEs 115, or any combination thereof. The communications may include communications over one or more wired interfaces, over one or more wireless interfaces, or any combination thereof. The device 1105 may include components that support outputting and obtaining communications, such as a communications manager 1120, a transceiver 1110, one or more antennas 1115, at least one memory 1125, code 1130, and at least one processor 1135. These components may be in electronic communication or otherwise coupled (e.g., operatively, communicatively, functionally, electronically, electrically) via one or more buses (e.g., a bus 1140).

The transceiver 1110 may support bi-directional communications via wired links, wireless links, or both as described herein. In some examples, the transceiver 1110 may include a wired transceiver and may communicate bi-directionally with another wired transceiver. Additionally, or alternatively, in some examples, the transceiver 1110 may include a wireless transceiver and may communicate bi-directionally with another wireless transceiver. In some examples, the device 1105 may include one or more antennas 1115, which may be capable of transmitting or receiving wireless transmissions (e.g., concurrently). The transceiver 1110 may also include a modem to modulate signals, to provide the modulated signals for transmission (e.g., by one or more antennas 1115, by a wired transmitter), to receive modulated signals (e.g., from one or more antennas 1115, from a wired receiver), and to demodulate signals. In some implementations, the transceiver 1110 may include one or more interfaces, such as one or more interfaces coupled with the one or more antennas 1115 that are configured to support various receiving or obtaining operations, or one or more interfaces coupled with the one or more antennas 1115 that are configured to support various transmitting or outputting operations, or a combination thereof. In some implementations, the transceiver 1110 may include or be configured for coupling with one or more processors or one or more memory components that are operable to perform or support operations based on received or obtained information or signals, or to generate information or other signals for transmission or other outputting, or any combination thereof. In some implementations, the transceiver 1110, or the transceiver 1110 and the one or more antennas 1115, or the transceiver 1110 and the one or more antennas 1115 and one or more processors or one or more memory components (e.g., the at least one processor 1135, the at least one memory 1125, or both), may be included in a chip or chip assembly that is installed in the device 1105. In some examples, the transceiver 1110 may be operable to support communications via one or more communications links (e.g., communication link(s) 125, backhaul communication link(s) 120, a midhaul communication link 162, a fronthaul communication link 168).

The at least one memory 1125 may include RAM, ROM, or any combination thereof. The at least one memory 1125 may store computer-readable, computer-executable, or processor-executable code, such as the code 1130. The code 1130 may include instructions that, when executed by one or more of the at least one processor 1135, cause the device 1105 to perform various functions described herein. The code 1130 may be stored in a non-transitory computer-readable medium such as system memory or another type of memory. In some cases, the code 1130 may not be directly executable by a processor of the at least one processor 1135 but may cause a computer (e.g., when compiled and executed) to perform functions described herein. In some cases, the at least one memory 1125 may include, among other things, a BIOS which may control basic hardware or software operation such as the interaction with peripheral components or devices. In some examples, the at least one processor 1135 may include multiple processors and the at least one memory 1125 may include multiple memories. One or more of the multiple processors may be coupled with one or more of the multiple memories which may, individually or collectively, be configured to perform various functions herein (for example, as part of a processing system).

The at least one processor 1135 may include one or more intelligent hardware devices (e.g., one or more general-purpose processors, one or more DSPs, one or more CPUs, one or more graphics processing units (GPUs), one or more neural processing units (NPUs) (also referred to as neural network processors or deep learning processors (DLPs)), one or more microcontrollers, one or more ASICs, one or more FPGAs, one or more programmable logic devices, discrete gate or transistor logic, one or more discrete hardware components, or any combination thereof). In some cases, the at least one processor 1135 may be configured to operate a memory array using a memory controller. In some other cases, a memory controller may be integrated into one or more of the at least one processor 1135. The at least one processor 1135 may be configured to execute computer-readable instructions stored in a memory (e.g., one or more of the at least one memory 1125) to cause the device 1105 to perform various functions (e.g., functions or tasks supporting CRC and PC generation for systematic polar coding). For example, the device 1105 or a component of the device 1105 may include at least one processor 1135 and at least one memory 1125 coupled with one or more of the at least one processor 1135, the at least one processor 1135 and the at least one memory 1125 configured to perform various functions described herein. The at least one processor 1135 may be an example of a cloud-computing platform (e.g., one or more physical nodes and supporting software such as operating systems, virtual machines, or container instances) that may host the functions (e.g., by executing code 1130) to perform the functions of the device 1105. The at least one processor 1135 may be any one or more suitable processors capable of executing scripts or instructions of one or more software programs stored in the device 1105 (such as within one or more of the at least one memory 1125).

In some examples, the at least one processor 1135 may include multiple processors and the at least one memory 1125 may include multiple memories. One or more of the multiple processors may be coupled with one or more of the multiple memories, which may, individually or collectively, be configured to perform various functions herein. In some examples, the at least one processor 1135 may be a component of a processing system, which may refer to a system (such as a series) of machines, circuitry (including, for example, one or both of processor circuitry (which may include the at least one processor 1135) and memory circuitry (which may include the at least one memory 1125)), or components, that receives or obtains inputs and processes the inputs to produce, generate, or obtain a set of outputs. The processing system may be configured to perform one or more of the functions described herein. For example, the at least one processor 1135 or a processing system including the at least one processor 1135 may be configured to, configurable to, or operable to cause the device 1105 to perform one or more of the functions described herein. Further, as described herein, being “configured to,” being “configurable to,” and being “operable to” may be used interchangeably and may be associated with a capability, when executing code stored in the at least one memory 1125 or otherwise, to perform one or more of the functions described herein.

In some examples, a bus 1140 may support communications of (e.g., within) a protocol layer of a protocol stack. In some examples, a bus 1140 may support communications associated with a logical channel of a protocol stack (e.g., between protocol layers of a protocol stack), which may include communications performed within a component of the device 1105, or between different components of the device 1105 that may be co-located or located in different locations (e.g., where the device 1105 may refer to a system in which one or more of the communications manager 1120, the transceiver 1110, the at least one memory 1125, the code 1130, and the at least one processor 1135 may be located in one of the different components or divided between different components).

In some examples, the communications manager 1120 may manage aspects of communications with a core network 130 (e.g., via one or more wired or wireless backhaul links). For example, the communications manager 1120 may manage the transfer of data communications for client devices, such as one or more UEs 115. In some examples, the communications manager 1120 may manage communications with one or more other network entities 105, and may include a controller or scheduler for controlling communications with UEs 115 (e.g., in cooperation with the one or more other network devices). In some examples, the communications manager 1120 may support an X2 interface within an LTE/LTE-A wireless communications network technology to provide communication between network entities 105.

The communications manager 1120 may support wireless communications in accordance with examples as disclosed herein. For example, the communications manager 1120 is capable of, configured to, or operable to support a means for inserting one or more error check bits into a set of multiple information bits, where the one or more error check bits are inserted prior to a first polar transform of a systematic polar coding procedure on the set of multiple information bits. The communications manager 1120 is capable of, configured to, or operable to support a means for encoding the set of multiple information bits and the one or more error check bits to generate a codeword via the first polar transform and a second polar transform in accordance with the systematic polar coding procedure, where the codeword includes the set of multiple information bits and the one or more error check bits. The communications manager 1120 is capable of, configured to, or operable to support a means for outputting the codeword based on the encoding.

Additionally, or alternatively, the communications manager 1120 may support wireless communications in accordance with examples as disclosed herein. For example, the communications manager 1120 is capable of, configured to, or operable to support a means for encoding a set of multiple information bits and one or more error check bits via a first polar transform and a second polar transform of a systematic polar coding procedure to generate a codeword. In some examples, to the encode, the communications manager 1120 may be configured as or otherwise support a means for applying the first polar transform to the set of multiple information bits and inserting the one or more error check bits after the first polar transform and prior to the second polar transform. The communications manager 1120 is capable of, configured to, or operable to support a means for outputting the codeword based on the encoding via the first polar transform and the second polar transform, where the codeword includes the set of multiple information bits.

By including or configuring the communications manager 1120 in accordance with examples as described herein, the device 1105 may support techniques for reduced complexity related to an encoding structure and improved performance related to a bit error rate.

In some examples, the communications manager 1120 may be configured to perform various operations (e.g., receiving, obtaining, monitoring, outputting, transmitting) using or otherwise in cooperation with the transceiver 1110, the one or more antennas 1115 (e.g., where applicable), or any combination thereof. Although the communications manager 1120 is illustrated as a separate component, in some examples, one or more functions described with reference to the communications manager 1120 may be supported by or performed by the transceiver 1110, one or more of the at least one processor 1135, one or more of the at least one memory 1125, the code 1130, or any combination thereof (for example, by a processing system including at least a portion of the at least one processor 1135, the at least one memory 1125, the code 1130, or any combination thereof). For example, the code 1130 may include instructions executable by one or more of the at least one processor 1135 to cause the device 1105 to perform various aspects of CRC and PC generation for systematic polar coding as described herein, or the at least one processor 1135 and the at least one memory 1125 may be otherwise configured to, individually or collectively, perform or support such operations.

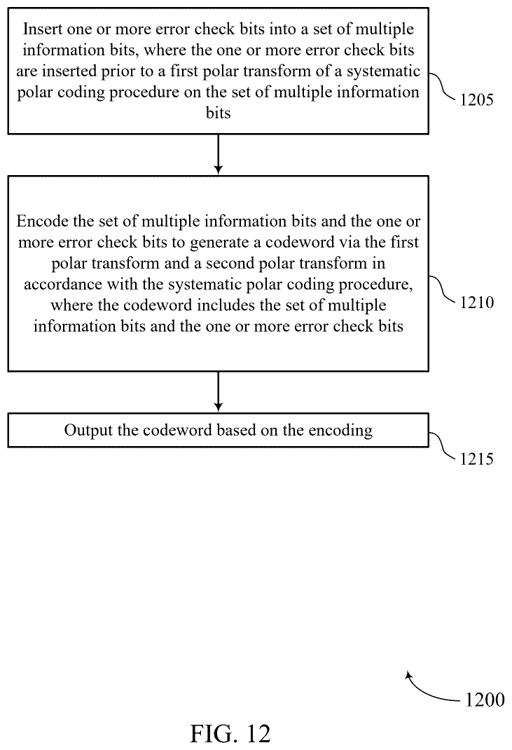

FIG. 12 shows a flowchart illustrating a method 1200 that supports CRC and PC generation for systematic polar coding in accordance with one or more aspects of the present disclosure. The operations of the method 1200 may be implemented by a network entity, a UE, or its components as described herein. For example, the operations of the method 1200 may be performed by a network entity or a UE as described with reference to FIGS. 1 through 11. In some examples, a network entity or a UE may execute a set of instructions to control the functional elements of the network entity or the UE to perform the described functions. Additionally, or alternatively, the network entity or the UE may perform aspects of the described functions using special-purpose hardware.

At 1205, the method may include inserting one or more error check bits into a set of multiple information bits, where the one or more error check bits are inserted prior to a first polar transform of a systematic polar coding procedure on the set of multiple information bits. The operations of 1205 may be performed in accordance with examples as disclosed herein. In some examples, aspects of the operations of 1205 may be performed by an error check bit insertion component 1025 as described with reference to FIG. 10.

At 1210, the method may include encoding the set of multiple information bits and the one or more error check bits to generate a codeword via the first polar transform and a second polar transform in accordance with the systematic polar coding procedure, where the codeword includes the set of multiple information bits and the one or more error check bits. The operations of 1210 may be performed in accordance with examples as disclosed herein. In some examples, aspects of the operations of 1210 may be performed by an encoding component 1030 as described with reference to FIG. 10.

At 1215, the method may include outputting the codeword based on the encoding. The operations of 1215 may be performed in accordance with examples as disclosed herein. In some examples, aspects of the operations of 1215 may be performed by a codeword component 1035 as described with reference to FIG. 10.

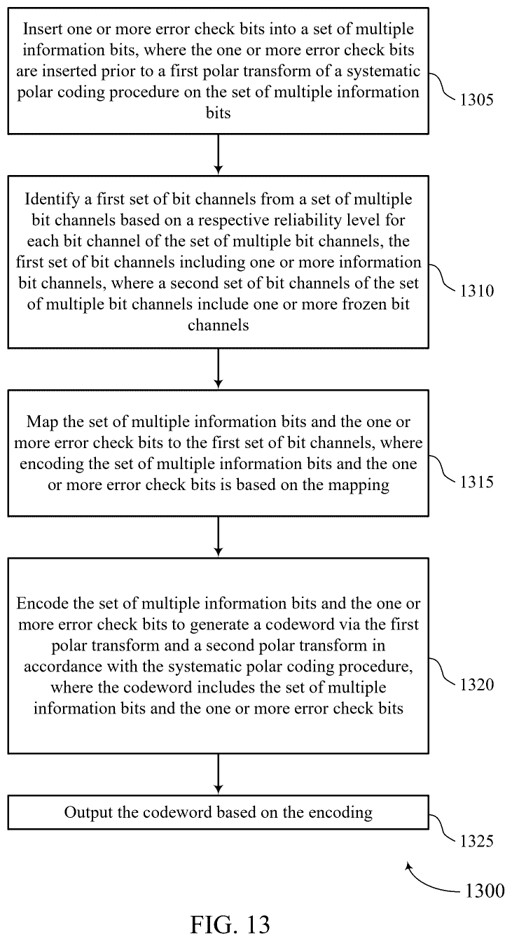

FIG. 13 shows a flowchart illustrating a method 1300 that supports CRC and PC generation for systematic polar coding in accordance with one or more aspects of the present disclosure. The operations of the method 1300 may be implemented by a network entity, a UE, or its components as described herein. For example, the operations of the method 1300 may be performed by a network entity or a UE as described with reference to FIGS. 1 through 11. In some examples, a network entity or a UE may execute a set of instructions to control the functional elements of the network entity or the UE to perform the described functions. Additionally, or alternatively, the network entity or the UE may perform aspects of the described functions using special-purpose hardware.

At 1305, the method may include inserting one or more error check bits into a set of multiple information bits, where the one or more error check bits are inserted prior to a first polar transform of a systematic polar coding procedure on the set of multiple information bits. The operations of 1305 may be performed in accordance with examples as disclosed herein. In some examples, aspects of the operations of 1305 may be performed by an error check bit insertion component 1025 as described with reference to FIG. 10.

At 1310, the method may include identifying a first set of bit channels from a set of multiple bit channels based on a respective reliability level for each bit channel of the set of multiple bit channels, the first set of bit channels including one or more information bit channels, where a second set of bit channels of the set of multiple bit channels include one or more frozen bit channels. The operations of 1310 may be performed in accordance with examples as disclosed herein. In some examples, aspects of the operations of 1310 may be performed by a reliability level component 1040 as described with reference to FIG. 10.

At 1315, the method may include mapping the set of multiple information bits and the one or more error check bits to the first set of bit channels, where encoding the set of multiple information bits and the one or more error check bits is based on the mapping. The operations of 1315 may be performed in accordance with examples as disclosed herein. In some examples, aspects of the operations of 1315 may be performed by a mapping component 1045 as described with reference to FIG. 10.

At 1320, the method may include encoding the set of multiple information bits and the one or more error check bits to generate a codeword via the first polar transform and a second polar transform in accordance with the systematic polar coding procedure, where the codeword includes the set of multiple information bits and the one or more error check bits. The operations of 1320 may be performed in accordance with examples as disclosed herein. In some examples, aspects of the operations of 1320 may be performed by an encoding component 1030 as described with reference to FIG. 10.

At 1325, the method may include outputting the codeword based on the encoding. The operations of 1325 may be performed in accordance with examples as disclosed herein. In some examples, aspects of the operations of 1325 may be performed by a codeword component 1035 as described with reference to FIG. 10.

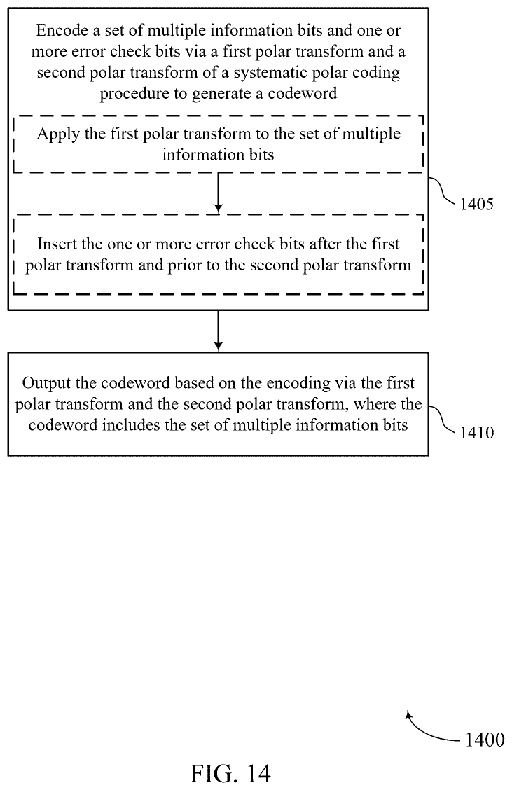

FIG. 14 shows a flowchart illustrating a method 1400 that supports CRC and PC generation for systematic polar coding in accordance with one or more aspects of the present disclosure. The operations of the method 1400 may be implemented by a network entity, a UE, or its components as described herein. For example, the operations of the method 1400 may be performed by a network entity or a UE as described with reference to FIGS. 1 through 11. In some examples, a network entity or a UE may execute a set of instructions to control the functional elements of the network entity or the UE to perform the described functions. Additionally, or alternatively, the network entity or the UE may perform aspects of the described functions using special-purpose hardware.

At 1405, the method may include encoding a set of multiple information bits and one or more error check bits via a first polar transform and a second polar transform of a systematic polar coding procedure to generate a codeword. In some examples, the encoding may include applying the first polar transform to the set of multiple information bits and inserting the one or more error check bits after the first polar transform and prior to the second polar transform. The operations of 1405 may be performed in accordance with examples as disclosed herein. In some examples, aspects of the operations of 1405 may be performed by an encoding component 1030 as described with reference to FIG. 10.

At 1410, the method may include outputting the codeword based on the encoding via the first polar transform and the second polar transform, where the codeword includes the set of multiple information bits. The operations of 1410 may be performed in accordance with examples as disclosed herein. In some examples, aspects of the operations of 1410 may be performed by a codeword component 1035 as described with reference to FIG. 10.

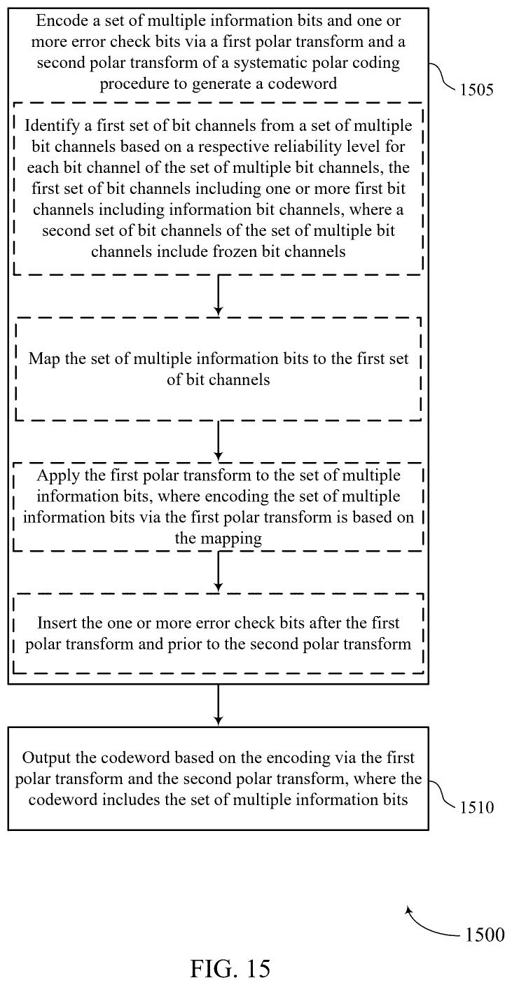

FIG. 15 shows a flowchart illustrating a method 1500 that supports CRC and PC generation for systematic polar coding in accordance with one or more aspects of the present disclosure. The operations of the method 1500 may be implemented by a network entity, a UE, or its components as described herein. For example, the operations of the method 1500 may be performed by a network entity or a UE as described with reference to FIGS. 1 through 11. In some examples, a network entity or a UE may execute a set of instructions to control the functional elements of the network entity or the UE to perform the described functions. Additionally, or alternatively, the network entity or the UE may perform aspects of the described functions using special-purpose hardware.

At 1505, the method may include encoding a set of multiple information bits and one or more error check bits via a first polar transform and a second polar transform of a systematic polar coding procedure to generate a codeword. In some examples, the method may include identifying a first set of bit channels from a set of multiple bit channels based on a respective reliability level for each bit channel of the set of multiple bit channels, the first set of bit channels including one or more first bit channels including information bit channels, where a second set of bit channels of the set of multiple bit channels include frozen bit channels. In some examples, the method may include mapping the set of multiple information bits to the first set of bit channels. In some examples, the encoding may include applying the first polar transform to the set of multiple information bits and inserting the one or more error check bits after the first polar transform and prior to the second polar transform, where encoding the set of multiple information bits via the first polar transform is based on the mapping. The operations of 1505 may be performed in accordance with examples as disclosed herein. In some examples, aspects of the operations of 1505 may be performed by an encoding component 1030 as described with reference to FIG. 10.

At 1510, the method may include outputting the codeword based on the encoding via the first polar transform and the second polar transform, where the codeword includes the set of multiple information bits. The operations of 1510 may be performed in accordance with examples as disclosed herein. In some examples, aspects of the operations of 1510 may be performed by a codeword component 1035 as described with reference to FIG. 10.

The following provides an overview of aspects of the present disclosure:

Aspect 1: A method for wireless communications at a wireless communication device, comprising: inserting one or more error check bits into a plurality of information bits, wherein the one or more error check bits are inserted prior to a first polar transform of a systematic polar coding procedure on the plurality of information bits; encoding the plurality of information bits and the one or more error check bits to generate a codeword via the first polar transform and a second polar transform in accordance with the systematic polar coding procedure, wherein the codeword comprises the plurality of information bits and the one or more error check bits; and outputting the codeword based at least in part on the encoding.

Aspect 2: The method of aspect 1, further comprising: identifying a first set of bit channels from a plurality of bit channels based at least in part on a respective reliability level for each bit channel of the plurality of bit channels, the first set of bit channels comprising one or more information bit channels, wherein a second set of bit channels of the plurality of bit channels comprise one or more frozen bit channels; and mapping the plurality of information bits and the one or more error check bits to the first set of bit channels, wherein encoding the plurality of information bits and the one or more error check bits is based at least in part on the mapping.

Aspect 3: The method of any of aspects 1 through 2, wherein the one or more error check bits comprise one or more CRC bits that are based at least in part on the plurality of information bits, the method further comprising: inserting one or more PC bits after the first polar transform and prior to the second polar transform of the systematic polar coding procedure, wherein the one or more PC bits are determined based at least in part on the plurality of information bits and the one or more CRC bits.

Aspect 4: The method of aspect 3, wherein respective values of the one or more PC bits are based at least in part on information bits of the plurality of information bits at bit channels after the first polar transform having lower indices than an index of a respective PC bit of the one or more PC bits.

Aspect 5: A method for wireless communications at a wireless communication device, comprising: encoding a plurality of information bits and one or more error check bits via a first polar transform and a second polar transform of a systematic polar coding procedure to generate a codeword, wherein the encoding comprises: applying the first polar transform to the plurality of information bits; and inserting the one or more error check bits after the first polar transform and prior to the second polar transform; and outputting the codeword based at least in part on the encoding via the first polar transform and the second polar transform, wherein the codeword comprises the plurality of information bits.

Aspect 6: The method of aspect 5, further comprising: identifying a first set of bit channels from a plurality of bit channels based at least in part on a respective reliability level for each bit channel of the plurality of bit channels, the first set of bit channels comprising one or more first bit channels comprising information bit channels, wherein a second set of bit channels of the plurality of bit channels comprise frozen bit channels; and mapping the plurality of information bits to the first set of bit channels, wherein encoding the plurality of information bits via the first polar transform is based at least in part on the mapping.

Aspect 7: The method of aspect 6, further comprising: inserting one or more bits having bit values of zero into one or more second bit channels of the first set of bit channels prior to the first polar transform.

Aspect 8: The method of any of aspects 6 through 7, wherein inserting the one or more error check bits comprises: inserting the one or more error check bits into one or more second bit channels of the first set of bit channels.

Aspect 9: The method of aspect 8, further comprising: generating the one or more error check bits, wherein the one or more error check bits comprise one or more CRC bits, and wherein inserting the one or more CRC bits further comprises: inserting the one or more CRC bits into the one or more second bit channels, wherein the one or more second bit channels precede the one or more first bit channels comprising the plurality of information bits.

Aspect 10: The method of any of aspects 6 through 9, further comprising: identifying a polar reliability sequence that orders the respective reliability level for each bit channel of the plurality of bit channels, wherein identifying the first set of bit channels is based at least in part on identifying the polar reliability sequence.

Aspect 11: The method of any of aspects 6 through 10, wherein the codeword comprises the plurality of information bits based at least in part on the first set of bit channels and the one or more first bit channels satisfying a condition.

Aspect 12: The method of aspect 11, wherein for a first set comprising the first set of bit channels and for a second set comprising the second set of bit channels, the condition comprises that one or more indices that are larger than a respective element of a plurality of elements of a set, based at least in part on a partial ordering, are included in the set.

Aspect 13: The method of any of aspects 5 through 12, further comprising: determine the one or more error check bits in accordance with a CRC code associated with a CRC condition, wherein the one or more error check bits and the plurality of information bits satisfy the CRC condition, and wherein inserting the one or more error check bits is based at least in part on determining the one or more error check bits.

Aspect 14: The method of any of aspects 5 through 13, wherein generating the one or more error check bits in accordance with a CRC condition, wherein inserting the one or more error check bits further comprises: inserting the one or more error check bits into one or more second bit channels of a first set of bit channels, wherein the one or more error check bits are inserted in an order of a first indexed bit channel to a last indexed bit channel of the one or more second bit channels.

Aspect 15: The method of any of aspects 5 through 14, further comprising: identifying a first set of bit channels from a plurality of bit channels based at least in part on a respective reliability level for each bit channel of the plurality of bit channels, the first set of bit channels comprising information bit channels; identifying a second set of bit channels from the plurality of bit channels, the second set of bit channels comprising PC bit channels; identifying a third set of bit channels of the plurality of bit channels, the third set of bit channels comprising frozen bit channels; and mapping the plurality of information bits to the first set of bit channels, wherein encoding the plurality of information bits via the first polar transform is based at least in part on the mapping.

Aspect 16: The method of aspect 15, wherein inserting the one or more error check bits comprises: inserting the one or more error check bits into the second set of bit channels.

Aspect 17: The method of any of aspects 15 through 16, wherein respective values of one or more PC bits are based at least in part on information bits of the plurality of information bits at bit channels after the first polar transform with lower indices than an index of a respective PC bit of the one or more PC bits.

Aspect 18: The method of any of aspects 5 through 17, wherein the one or more error check bits comprise one or more CRC bits or one or more PC bits.

Aspect 19: The method of any of aspects 5 through 18, further comprising: inserting one or more CRC bits into the plurality of information bits prior to the first polar transform, wherein the one or more CRC bits are determined based at least in part on the plurality of information bits; and inserting the one or more error check bits after the first polar transform and prior to the second polar transform of the systematic polar coding procedure, wherein the one or more error check bits comprise one or more PC bits, and wherein the one or more PC bits are determined based at least in part on the plurality of information bits and the one or more error check bits.

Aspect 20: The method of any of aspects 5 through 19, wherein the one or more error check bits comprise one or more CRC bits and one or more PC bits, the method further comprising: inserting the one or more CRC bits after the first polar transform and prior to the second polar transform of the systematic polar coding procedure, wherein a first quantity of the one or more CRC bits satisfies a CRC condition; and inserting the one or more PC bits after the first polar transform and prior to the second polar transform of the systematic polar coding procedure, wherein a second quantity of the one or more PC bits satisfies a PC relationship.

Aspect 21: A wireless communication device for wireless communications, comprising one or more memories storing processor-executable code, and one or more processors coupled with the one or more memories and individually or collectively operable to execute the code to cause the wireless communication device to perform a method of any of aspects 1 through 4.

Aspect 22: A wireless communication device for wireless communications, comprising at least one means for performing a method of any of aspects 1 through 4.

Aspect 23: A non-transitory computer-readable medium storing code for wireless communications, the code comprising instructions executable by one or more processors to perform a method of any of aspects 1 through 4.

Aspect 24: A wireless communication device for wireless communications, comprising one or more memories storing processor-executable code, and one or more processors coupled with the one or more memories and individually or collectively operable to execute the code to cause the wireless communication device to perform a method of any of aspects 5 through 20.

Aspect 25: A wireless communication device for wireless communications, comprising at least one means for performing a method of any of aspects 5 through 20.

Aspect 26: A non-transitory computer-readable medium storing code for wireless communications, the code comprising instructions executable by one or more processors to perform a method of any of aspects 5 through 20.

It should be noted that the methods described herein describe possible implementations. The operations and the steps may be rearranged or otherwise modified and other implementations are possible. Further, aspects from two or more of the methods may be combined.

Although aspects of an LTE, LTE-A, LTE-A Pro, or NR system may be described for purposes of example, and LTE, LTE-A, LTE-A Pro, or NR terminology may be used in much of the description, the techniques described herein are applicable beyond LTE, LTE-A, LTE-A Pro, or NR networks. For example, the described techniques may be applicable to various other wireless communications systems such as Ultra Mobile Broadband (UMB), Institute of Electrical and Electronics Engineers (IEEE) 802.11 (Wi-Fi), IEEE 802.16 (WiMAX), IEEE 802.20, Flash-OFDM, as well as other systems and radio technologies not explicitly mentioned herein.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and components described in connection with the disclosure herein may be implemented or performed using a general-purpose processor, a DSP, an ASIC, a CPU, a graphics processing unit (GPU), a neural processing unit (NPU), an FPGA or other programmable logic device, discrete gate or transistor logic, discrete hardware components, or any combination thereof designed to perform the functions described herein. A general-purpose processor may be a microprocessor but, in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration). Any functions or operations described herein as being capable of being performed by a processor may be performed by multiple processors that, individually or collectively, are capable of performing the described functions or operations.

The functions described herein may be implemented using hardware, software executed by a processor, firmware, or any combination thereof. If implemented using software executed by a processor, the functions may be stored as or transmitted using one or more instructions or code of a computer-readable medium. Other examples and implementations are within the scope of the disclosure and appended claims. For example, due to the nature of software, functions described herein may be implemented using software executed by a processor, hardware, firmware, hardwiring, or combinations of any of these. Features implementing functions may also be physically located at various positions, including being distributed such that portions of functions are implemented at different physical locations.

Computer-readable media includes both non-transitory computer storage media and communication media including any medium that facilitates transfer of a computer program from one location to another. A non-transitory storage medium may be any available medium that may be accessed by a general-purpose or special-purpose computer. By way of example, and not limitation, non-transitory computer-readable media may include RAM, ROM, electrically erasable programmable ROM (EEPROM), flash memory, compact disk (CD) ROM or other optical disk storage, magnetic disk storage or other magnetic storage devices, or any other non-transitory medium that may be used to carry or store desired program code means in the form of instructions or data structures and that may be accessed by a general-purpose or special-purpose computer or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of computer-readable medium. Disk and disc, as used herein, include CD, laser disc, optical disc, digital versatile disc (DVD), floppy disk, and Blu-ray disc. Disks may reproduce data magnetically, and discs may reproduce data optically using lasers. Combinations of the above are also included within the scope of computer-readable media. Any functions or operations described herein as being capable of being performed by a memory may be performed by multiple memories that, individually or collectively, are capable of performing the described functions or operations.

As used herein, including in the claims, “or” as used in a list of items (e.g., a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” and “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

The term “determine” or “determining” encompasses a variety of actions and, therefore, “determining” can include calculating, computing, processing, deriving, investigating, looking up (such as via looking up in a table, a database, or another data structure), ascertaining, and the like. Also, “determining” can include receiving (e.g., receiving information), accessing (e.g., accessing data stored in memory), and the like. Also, “determining” can include resolving, obtaining, selecting, choosing, establishing, and other such similar actions.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label or other subsequent reference label.

The description set forth herein, in connection with the appended drawings, describes example configurations and does not represent all the examples that may be implemented or that are within the scope of the claims. The term “example” used herein means “serving as an example, instance, or illustration” and not “preferred” or “advantageous over other examples.” The detailed description includes specific details for the purpose of providing an understanding of the described techniques. These techniques, however, may be practiced without these specific details. In some figures, known structures and devices are shown in block diagram form in order to avoid obscuring the concepts of the described examples.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A wireless communication device, comprising:
one or more memories storing processor-executable code; and
one or more processors coupled with the one or more memories and individually or collectively operable to execute the code to cause the wireless communication device to:
insert one or more error check bits into a plurality of information bits, wherein the one or more error check bits are inserted prior to a first polar transform of a systematic polar coding procedure on the plurality of information bits;
encode the plurality of information bits and the one or more error check bits to generate a codeword via the first polar transform and a second polar transform in accordance with the systematic polar coding procedure, wherein the codeword comprises the plurality of information bits and the one or more error check bits; and
output the codeword based at least in part on the encoding.

2. The wireless communication device of claim 1, wherein the one or more processors are individually or collectively further operable to execute the code to cause the wireless communication device to:
identify a first set of bit channels from a plurality of bit channels based at least in part on a respective reliability level for each bit channel of the plurality of bit channels, the first set of bit channels comprising one or more information bit channels, wherein a second set of bit channels of the plurality of bit channels comprise one or more frozen bit channels; and
map the plurality of information bits and the one or more error check bits to the first set of bit channels, wherein encoding the plurality of information bits and the one or more error check bits is based at least in part on the mapping.

3. The wireless communication device of claim 1, wherein the one or more error check bits comprise one or more cyclic redundancy check bits that are based at least in part on the plurality of information bits, and the one or more processors are individually or collectively further operable to execute the code to cause the wireless communication device to:
insert one or more parity check bits after the first polar transform and prior to the second polar transform of the systematic polar coding procedure, wherein the one or more parity check bits are determined based at least in part on the plurality of information bits and the one or more cyclic redundancy check bits.

4. The wireless communication device of claim 3, wherein respective values of the one or more parity check bits are based at least in part on information bits of the plurality of information bits at bit channels after the first polar transform having lower indices than an index of a respective parity check bit of the one or more parity check bits.

5. A wireless communication device, comprising:
one or more memories storing processor-executable code; and
one or more processors coupled with the one or more memories and individually or collectively operable to execute the code to cause the wireless communication device to:
encode a plurality of information bits and one or more error check bits via a first polar transform and a second polar transform of a systematic polar coding procedure to generate a codeword, wherein, to the encode, the one or more processors are individually or collectively operable to execute the code to cause the wireless communication device to:
apply the first polar transform to the plurality of information bits; and
insert the one or more error check bits after the first polar transform and prior to the second polar transform; and
output the codeword based at least in part on the encoding via the first polar transform and the second polar transform, wherein the codeword comprises the plurality of information bits.

6. The wireless communication device of claim 5, wherein the one or more processors are individually or collectively further operable to execute the code to cause the wireless communication device to:
identify a first set of bit channels from a plurality of bit channels based at least in part on a respective reliability level for each bit channel of the plurality of bit channels, the first set of bit channels comprising one or more first bit channels comprising information bit channels, wherein a second set of bit channels of the plurality of bit channels comprise frozen bit channels; and
map the plurality of information bits to the first set of bit channels, wherein encoding the plurality of information bits via the first polar transform is based at least in part on the mapping.

7. The wireless communication device of claim 6, wherein the one or more processors are individually or collectively further operable to execute the code to cause the wireless communication device to:
insert one or more bits having bit values of zero into one or more second bit channels of the first set of bit channels prior to the first polar transform.

8. The wireless communication device of claim 6, wherein, to insert the one or more error check bits, the one or more processors are individually or collectively operable to execute the code to cause the wireless communication device to:
insert the one or more error check bits into one or more second bit channels of the first set of bit channels.

9. The wireless communication device of claim 8, wherein the one or more processors are individually or collectively further operable to execute the code to cause the wireless communication device to:
generate the one or more error check bits, wherein the one or more error check bits comprise one or more cyclic redundancy check bits, and wherein inserting the one or more cyclic redundancy check bits further comprises:
insert the one or more cyclic redundancy check bits into the one or more second bit channels, wherein the one or more second bit channels precede the one or more first bit channels comprising the plurality of information bits.

10. The wireless communication device of claim 6, wherein the one or more processors are individually or collectively further operable to execute the code to cause the wireless communication device to:
identify a polar reliability sequence that orders the respective reliability level for each bit channel of the plurality of bit channels, wherein identifying the first set of bit channels is based at least in part on identifying the polar reliability sequence.

11. The wireless communication device of claim 6, wherein the codeword comprises the plurality of information bits based at least in part on the first set of bit channels and the one or more first bit channels satisfying a condition.

12. The wireless communication device of claim 11, wherein for a first set comprising the first set of bit channels and for a second set comprising the second set of bit channels, the condition comprises that one or more indices that are larger than a respective element of a plurality of elements of a set, based at least in part on a partial ordering, are included in the set.

13. The wireless communication device of claim 5, wherein the one or more processors are individually or collectively further operable to execute the code to cause the wireless communication device to:
determine the one or more error check bits in accordance with a cyclic redundancy check code associated with a cyclic redundancy check condition, wherein the one or more error check bits and the plurality of information bits satisfy the cyclic redundancy check condition, and wherein inserting the one or more error check bits is based at least in part on determining the one or more error check bits.

14. The wireless communication device of claim 5, wherein the one or more processors are individually or collectively further operable to execute the code to cause the wireless communication device to:
generate the one or more error check bits in accordance with a cyclic redundancy check condition, wherein, to insert the one or more error check bits, the one or more processors are individually or collectively operable to execute the code to cause the wireless communication device to:
insert the one or more error check bits into one or more second bit channels of a first set of bit channels, wherein the one or more error check bits are inserted in an order of a first indexed bit channel to a last indexed bit channel of the one or more second bit channels.

15. The wireless communication device of claim 5, wherein the one or more processors are individually or collectively further operable to execute the code to cause the wireless communication device to:
identify a first set of bit channels from a plurality of bit channels based at least in part on a respective reliability level for each bit channel of the plurality of bit channels, the first set of bit channels comprising information bit channels;
identify a second set of bit channels from the plurality of bit channels, the second set of bit channels comprising parity check bit channels;
identify a third set of bit channels of the plurality of bit channels, the third set of bit channels comprising frozen bit channels; and
map the plurality of information bits to the first set of bit channels, wherein encoding the plurality of information bits via the first polar transform is based at least in part on the mapping.

16. The wireless communication device of claim 15, wherein, to insert the one or more error check bits, the one or more processors are individually or collectively operable to execute the code to cause the wireless communication device to:
insert the one or more error check bits into the second set of bit channels.

17. The wireless communication device of claim 15, wherein respective values of one or more parity check bits are based at least in part on information bits of the plurality of information bits at bit channels after the first polar transform with lower indices than an index of a respective parity check bit of the one or more parity check bits.

18. The wireless communication device of claim 5, wherein the one or more error check bits comprise one or more cyclic redundancy check bits or one or more parity check bits.

19. The wireless communication device of claim 5, wherein the one or more processors are individually or collectively further operable to execute the code to cause the wireless communication device to:
insert one or more cyclic redundancy check bits into the plurality of information bits prior to the first polar transform, wherein the one or more cyclic redundancy check bits are determined based at least in part on the plurality of information bits; and
insert the one or more error check bits after the first polar transform and prior to the second polar transform of the systematic polar coding procedure, wherein the one or more error check bits comprise one or more parity check bits, and wherein the one or more parity check bits are determined based at least in part on the plurality of information bits and the one or more error check bits.

20. The wireless communication device of claim 5, wherein the one or more error check bits comprise one or more cyclic redundancy check bits and one or more parity check bits, and the one or more processors are individually or collectively further operable to execute the code to cause the wireless communication device to:
insert the one or more cyclic redundancy check bits after the first polar transform and prior to the second polar transform of the systematic polar coding procedure, wherein a first quantity of the one or more cyclic redundancy check bits satisfies a cyclic redundancy check condition; and
insert the one or more parity check bits after the first polar transform and prior to the second polar transform of the systematic polar coding procedure, wherein a second quantity of the one or more parity check bits satisfies a parity check relationship.

21. A method for wireless communications at a wireless communication device, comprising:
inserting one or more error check bits into a plurality of information bits, wherein the one or more error check bits are inserted prior to a first polar transform of a systematic polar coding procedure on the plurality of information bits;
encoding the plurality of information bits and the one or more error check bits to generate a codeword via the first polar transform and a second polar transform in accordance with the systematic polar coding procedure, wherein the codeword comprises the plurality of information bits and the one or more error check bits; and
outputting the codeword based at least in part on the encoding.

22. The method of claim 21, further comprising:
identifying a first set of bit channels from a plurality of bit channels based at least in part on a respective reliability level for each bit channel of the plurality of bit channels, the first set of bit channels comprising one or more information bit channels, wherein a second set of bit channels of the plurality of bit channels comprise one or more frozen bit channels; and
mapping the plurality of information bits and the one or more error check bits to the first set of bit channels, wherein encoding the plurality of information bits and the one or more error check bits is based at least in part on the mapping.

23. The method of claim 21, wherein the one or more error check bits comprise one or more cyclic redundancy check bits that are based at least in part on the plurality of information bits, the method further comprising:
inserting one or more parity check bits after the first polar transform and prior to the second polar transform of the systematic polar coding procedure, wherein the one or more parity check bits are determined based at least in part on the plurality of information bits and the one or more cyclic redundancy check bits.

24. The method of claim 23, wherein respective values of the one or more parity check bits are based at least in part on information bits of the plurality of information bits at bit channels after the first polar transform having lower indices than an index of a respective parity check bit of the one or more parity check bits.

25. A method for wireless communications at a wireless communication device, comprising:
encoding a plurality of information bits and one or more error check bits via a first polar transform and a second polar transform of a systematic polar coding procedure to generate a codeword, wherein the encoding comprises:
applying the first polar transform to the plurality of information bits; and
inserting the one or more error check bits after the first polar transform and prior to the second polar transform; and
outputting the codeword based at least in part on the encoding via the first polar transform and the second polar transform, wherein the codeword comprises the plurality of information bits.

26. The method of claim 25, further comprising:
identifying a first set of bit channels from a plurality of bit channels based at least in part on a respective reliability level for each bit channel of the plurality of bit channels, the first set of bit channels comprising one or more first bit channels comprising information bit channels, wherein a second set of bit channels of the plurality of bit channels comprise frozen bit channels; and
mapping the plurality of information bits to the first set of bit channels, wherein encoding the plurality of information bits via the first polar transform is based at least in part on the mapping.

27. The method of claim 26, further comprising:
inserting one or more bits having bit values of zero into one or more second bit channels of the first set of bit channels prior to the first polar transform.

28. The method of claim 26, wherein inserting the one or more error check bits comprises:
inserting the one or more error check bits into one or more second bit channels of the first set of bit channels.

29. The method of claim 28, further comprising:
generating the one or more error check bits, wherein the one or more error check bits comprise one or more cyclic redundancy check bits, and wherein inserting the one or more cyclic redundancy check bits further comprises:
inserting the one or more cyclic redundancy check bits into the one or more second bit channels, wherein the one or more second bit channels precede the one or more first bit channels comprising the plurality of information bits.

30. The method of claim 26, further comprising:
identifying a polar reliability sequence that orders the respective reliability level for each bit channel of the plurality of bit channels, wherein identifying the first set of bit channels is based at least in part on identifying the polar reliability sequence.
